(19) United States
(12) Patent Application Publication
(10) Pub. No.: US 2020/0091220 A1
(43) Pub. Date: Mar. 19, 2020

(54) ACTIVE MATRIX SUBSTRATE, X-RAY IMAGING PANEL WITH THE SAME, AND METHOD OF MANUFACTURING THE SAME

(71) Applicant: SHARP KABUSHIKI KAISHA, Sakai City (JP)

(72) Inventor: KATSUNORI MISAKI, Yonago-shi (JP)

(21) Appl. No.: 16/568,833

(22) Filed: Sep. 12, 2019

Related U.S. Application Data
(60) Provisional application No. 62/731,580, filed on Sep. 14, 2018.

(51) Int. Cl. H01L 27/146; H01L 31/0216; H01L 31/0224; G01T 1/20

(52) U.S. Cl. CPC H01L 27/14663; H01L 27/14685; H01L 27/14636; H01L 27/1462; G01T 1/2018; H01L 31/022408; H01L 27/14612; H01L 31/022466; H01L 31/0216

(57) ABSTRACT

An active matrix substrate includes a photoelectric conversion element, an electrode provided on at least one main surface of the photoelectric conversion element, and a first inorganic film covering a side surface of the photoelectric conversion element. The electrode includes an extending section covering the side surface of the photoelectric conversion element through intermediation of the first inorganic film.

### CROSS-REFERENCE TO RELATED APPLICATIONS

This application claims the benefit of priority to U.S. Provisional Application No. 62/731,580 filed on Sep. 14, 2018. The entire contents of the above-identified application are hereby incorporated by reference.

### BACKGROUND

### Technical Field

The disclosure disclosed in the following relates to an active matrix substrate, an X-ray imaging panel including the same, and a manufacturing method of an active matrix substrate.

JP 2007-165865 A discloses a photoelectric conversion device including a thin film transistor and a photodiode. The photodiode is formed of a semiconductor layer having a PIN structure in which a p-type semiconductor layer, an i-type semiconductor layer, and an n-type semiconductor layer are layered and a pair of electrodes sandwiching the semiconductor layer, and the photodiode is covered with a resin film.

Incidentally, after an imaging panel is manufactured, the surface of the imaging panel is damaged in some cases. In a case where moisture in the atmosphere enters through a scratch in the surface of the imaging panel, a leakage current in the semiconductor layers of the photodiode is liable to flow between the electrodes. For example, in an imaging panel illustrated in FIG. 14, in a case where moisture enters through a scratch J formed in a surface of an imaging panel, the moisture penetrates a resin film 92 on a photodiode 90. In a case where an inorganic film 91 covering the photodiode 90 is formed through use of a plasma CVD device, a speed at which the inorganic film 91 is formed differs between side surface parts of the photodiode 90 and flat parts of the photodiode 90 other than the side surface parts, and hence the inorganic film 91 is less likely to be formed uniformly. As a result, parts of the inorganic film 91, which cover the side surface parts of the photodiode 90 and are indicated with broken line circles 900a, are liable to be discontinuous. In a case where moisture enters through the discontinuous parts of the inorganic film 91, a leakage current in semiconductor layers 900 of the photodiode 90 is liable to flow, which causes degradation of detection accuracy of an X-ray.

### SUMMARY

An active matrix substrate, which is achieved in view of the above-described problem, includes a photoelectric conversion element; an electrode provided on at least one main surface of the photoelectric conversion element; and a first inorganic film covering a side surface of the photoelectric conversion element, wherein the electrode includes an extending section covering the side surface of the photoelectric conversion element through intermediation of the first inorganic film.

According to the above-described configuration, a leakage current of the photoelectric conversion element is less liable to flow even in a case where moisture enters the active matrix substrate.

### BRIEF DESCRIPTION OF DRAWINGS

The disclosure will be described with reference to the accompanying drawings, wherein like numbers reference like elements.

FIG. 1 is a schematic view illustrating an X-ray imaging device according to a first embodiment.

FIG. 2 is a schematic view illustrating an outline configuration of an active matrix substrate illustrated in FIG. 1.

FIG. 3 is a plan view obtained by enlarging a part of pixels of the active matrix substrate illustrated in FIG. 2.

FIG. 4A is a cross-sectional view taken along the line A-A of the pixel in FIG. 3.

FIG. 4B is a cross-sectional view obtained by extracting and enlarging a part of the configuration including an upper electrode illustrated in FIG. 4A.

FIG. 5A is a view illustrating a step of forming a pixel configuration of the active matrix substrate illustrated in FIGS. 4A and 4B and a cross-sectional view illustrating a state in which a TFT is formed.

FIG. 5B is a cross-sectional view illustrating a step of forming a first insulating film illustrated in FIG. 4A.

FIG. 5C is a cross-sectional view illustrating a step of forming an opening of the first insulating film illustrated in FIG. 5B.

FIG. 5D is a cross-sectional view illustrating a step of forming a second insulating film illustrated in FIGS. 4A and 4B.

FIG. 5E is a cross-sectional view illustrating a step of forming an opening of the second insulating film illustrated in FIG. 5D and forming a contact hole CH1 illustrated in FIG. 4A.

FIG. 5F is a cross-sectional view illustrating a step of forming a lower electrode (cathode electrode) illustrated in FIGS. 4A and 4B.

FIG. 5G is a cross-sectional view illustrating a step of forming semiconductor layers as a photoelectric conversion layer illustrated in FIGS. 4A and 4B.

FIG. 5H is a cross-sectional view illustrating a step of forming the photoelectric conversion layer by patterning the semiconductor layers illustrated in FIG. 5G.

FIG. 5I is a cross-sectional view illustrating a step of forming a third insulating film illustrated in FIGS. 4A and 4B.

FIG. 5J is a cross-sectional view illustrating a step of forming an opening of the third insulating film illustrated in FIG. 5I.

FIG. 5K is a cross-sectional view illustrating a step of forming a transparent conductive film as the upper electrode (anode electrode) illustrated in FIGS. 4A and 4B.

FIG. 5L is a cross-sectional view illustrating a step of forming the upper electrode by patterning the transparent conductive film illustrated in FIG. 5K.

FIG. 5M is a cross-sectional view illustrating a step of forming a fourth insulating film illustrated in FIG. 4A.

FIG. 5N is a cross-sectional view illustrating a step of forming an opening of the fourth insulating film illustrated in FIG. 5M.

FIG. 5O is a cross-sectional view illustrating a step of forming a bias wiring line illustrated in FIG. 4A.

FIG. 5P is a cross-sectional view illustrating a step of forming a transparent conductive film to be connected to the bias wiring line and the upper electrode illustrated in FIG. 4A.

FIG. 5Q is a cross-sectional view illustrating a step of forming a fifth insulating film illustrated in FIG. 4A.

FIG. 5R is a cross-sectional view illustrating a step of forming a sixth insulating film illustrated in FIG. 4A.

FIG. 6A is a cross-sectional view illustrating an outline configuration of a pixel of an active matrix substrate according to a second embodiment.

FIG. 6B is a cross-sectional view illustrating a manufacturing process of the pixel of the active matrix substrate illustrated in FIG. 6A and cross-sectional view illustrating a step of forming an inorganic insulating film covering an upper electrode illustrated in FIG. 6A.

FIG. 6C is a cross-sectional view illustrating an outline configuration of a pixel of an active matrix substrate in a modified example of the second embodiment.

FIG. 7A is a cross-sectional view illustrating an outline configuration of a pixel of an active matrix substrate according to a third embodiment.

FIG. 7B is a cross-sectional view illustrating a manufacturing process of the pixel of the active matrix substrate illustrated in FIG. 7A and a cross-sectional view illustrating a step of forming a transparent resin film overlapping with an upper electrode illustrated in FIG. 7A.

FIG. 8 is a cross-sectional view illustrating an overall configuration of a pixel of an active matrix substrate in Modified Example 1 of the third embodiment.

FIG. 9A is a cross-sectional view illustrating manufacturing process of the pixel of the active matrix substrate illustrated in FIG. 8 and a cross-sectional view illustrating a step of forming a transparent resin film illustrated in FIG. 8.

FIG. 9B is a cross-sectional view illustrating a step of patterning the transparent resin film illustrated in FIG. 9A.

FIG. 9C is a cross-sectional view illustrating a step of forming an inorganic insulating film on the transparent resin film illustrated in FIG. 9B.

FIG. 9D is a cross-sectional view illustrating a step of forming an opening of the inorganic insulating film by patterning the inorganic insulating film illustrated in FIG. 9C.

FIG. 9E is a cross-sectional view illustrating a step of forming an organic resin film as a fourth insulating film on the inorganic insulating film illustrated in FIG. 9D.

FIG. 9F is a cross-sectional view illustrating a step of forming an opening of the organic resin film by patterning the organic resin film illustrated in FIG. 9E.

FIG. 10A is a cross-sectional view illustrating an overall configuration of a pixel of an active matrix substrate in Modified Example 2 of the third embodiment.

FIG. 10B is a cross-sectional view of the pixel of the active matrix substrate in Modified Example 2 of the third embodiment, which has a pixel structure different from that in FIG. 10A.

FIG. 10C is a cross-sectional view illustrating an overall configuration of a pixel of an active matrix substrate in Modified Example 3 of the third embodiment.

FIG. 11A is a cross-sectional view illustrating an overall configuration of a pixel of an active matrix substrate according to a fourth embodiment.

FIG. 11B is a cross-sectional view of the pixel of the active matrix substrate according to the fourth embodiment, which has a pixel structure different from that in FIG. 11A.

FIG. 12 is a cross-sectional view illustrating an overall configuration of a pixel of an active matrix substrate in Modified Example 1.

FIG. 13 is a cross-sectional view illustrating an overall configuration of a pixel of an active matrix substrate in Modified Example 2.

FIG. 14 is a cross-sectional view illustrating a configuration example of a pixel of an active matrix substrate in the related art.

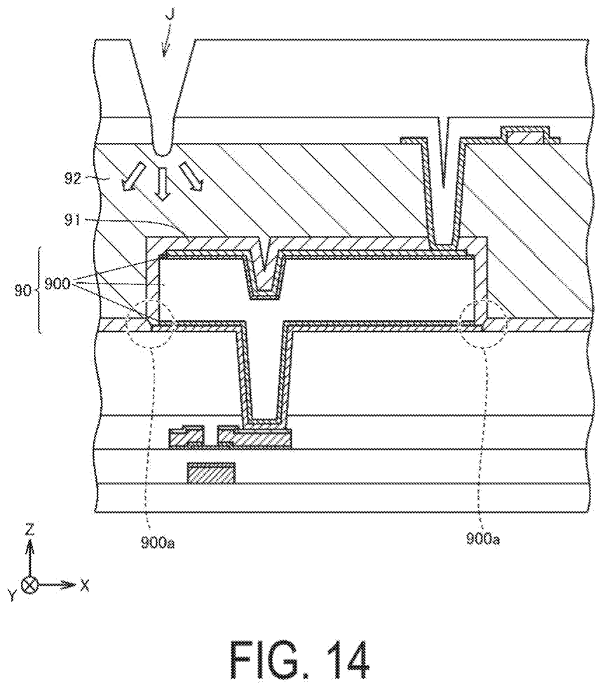

### DESCRIPTION OF EMBODIMENTS

Now, with reference to the drawings, description is provided on embodiments of the disclosure. In the drawings, the same or corresponding parts are denoted with the same reference signs, and description therefor is not repeated.

### First Embodiment

### Configuration

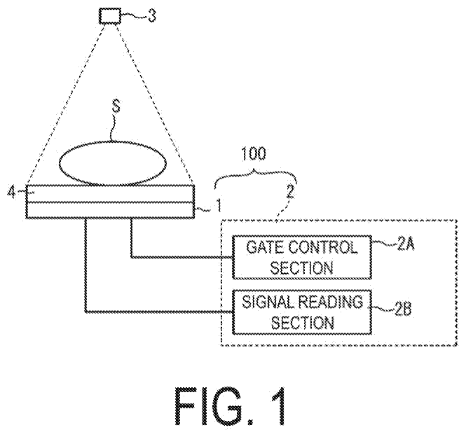

FIG. 1 is a schematic view illustrating an X-ray imaging device to which an active matrix substrate according to the present embodiment is applied. An X-ray imaging device 100 includes an active matrix substrate 1, a controller 2, an X-ray source 3, and a scintillator 4. In the present embodiment, an imaging panel includes at least the active matrix substrate 1 and the scintillator 4.

The controller 2 includes a gate control section 2A and a signal reading section 2B. A subject S is irradiated with an X-ray from the X-ray source 3. The X-ray passing through the subject S is converted into fluorescence (hereinafter, scintillation light) at the scintillator 4 arranged on an upper part of the active matrix substrate 1. The X-ray imaging device 100 acquires an X-ray image by capturing an image of the scintillation light with the active matrix substrate 1 and the controller 2.

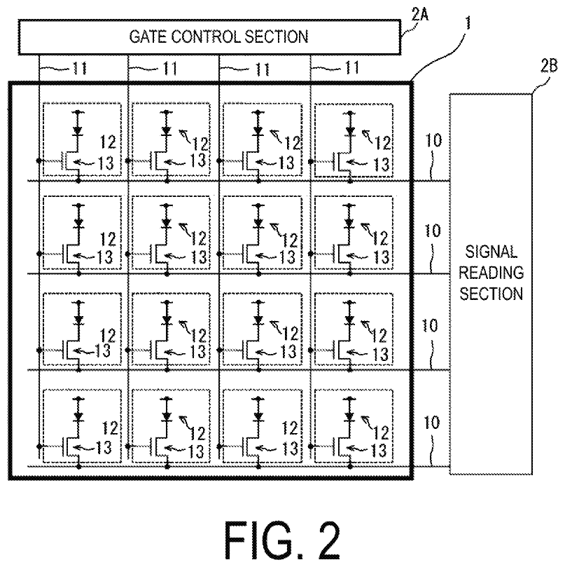

FIG. 2 is a schematic view illustrating an overall configuration of the active matrix substrate 1. As illustrated in FIG. 2, a plurality of source wiring lines 10 and a plurality of gate wiring lines 11 intersecting the plurality of source wiring lines 10 are formed on the active matrix substrate 1. The gate wiring lines 11 are connected to the gate control section 2A, and the source wiring lines 10 are connected to the signal reading section 2B.

At positions at which the source wiring lines 10 and the gate wiring lines 11 intersect each other, the active matrix substrate 1 includes TFTs 13 connected to the source wiring lines 10 and the gate wiring line 11. Photodiodes 12 are provided in regions surrounded by the source wiring lines 10 and the gate wiring lines 11 (hereinafter, pixels). In the pixels, the photodiodes 12 convert the scintillation light, which is obtained by converting the X-ray passing through the subject S, into electric charges depending on a light amount of the scintillation light.

Each of the gate wiring lines 11 is sequentially switched to a select state by the gate control section 2A, and the TFT 13 connected to the gate wiring line 11 in the select state turns to an on state. In a case where the TFT 13 is in the on state, a signal corresponding to the electric charge converted by the photodiode 12 is output to the signal reading section 2B via the source wiring line 10.

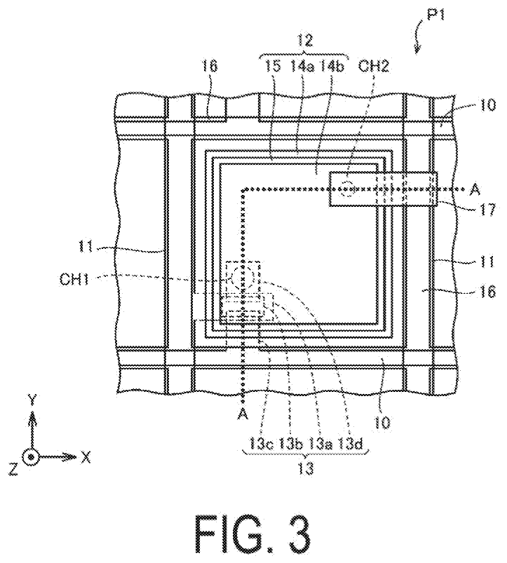

FIG. 3 is a plan view obtained by enlarging a pixel being a part of the active matrix substrate 1 illustrated in FIG. 2.

As illustrated in FIG. 3, the photodiode 12 and the TFT 13 are provided in a pixel P1 surrounded by the gate wiring lines 11 and the source wiring lines 10.

The photodiode 12 includes a lower electrode (cathode electrode) 14a, a photoelectric conversion layer 15, and an upper electrode (anode electrode) 14b. The TFT 13 includes a gate electrode 13a connected to the gate wiring line 11, a semiconductor active layer 13b, a source electrode 13c connected to the source wiring line 10, and a drain electrode 13d. The drain electrode 13d and the lower electrode 14a are connected to each other through a contact hole CH1.

Bias wiring lines 16 are arranged to overlap with the gate wiring lines 11 and the source wiring lines 10 in a plan view. The bias wiring lines 16 are connected to a transparent conductive film 17. The transparent conductive film 17 is connected to the photodiode 12 through a contact hole CH2, and supplies a bias voltage to the upper electrode 14b of the photodiode 12.

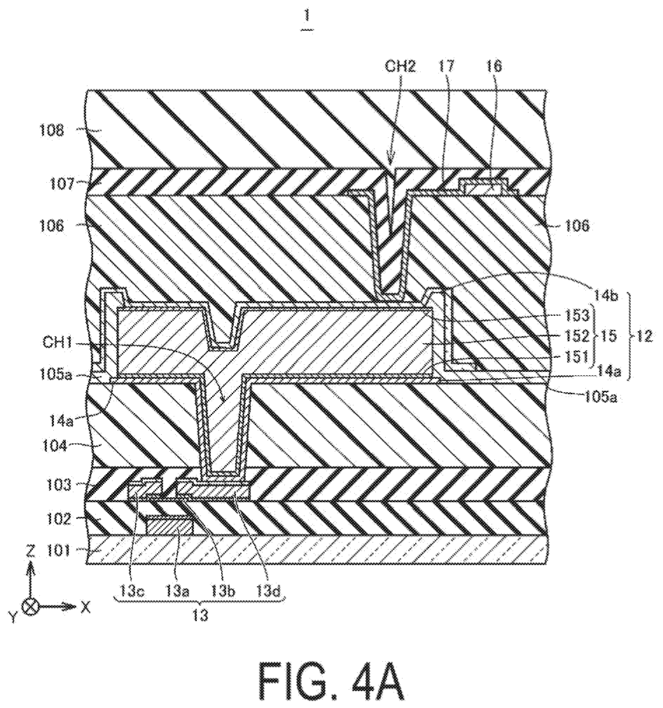

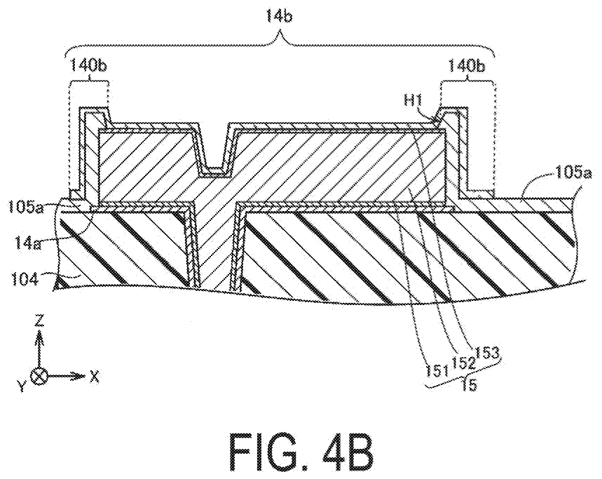

Now, a cross-sectional view taken along the line A-A of the pixel P1 in FIG. 3 is given in FIG. 4A. In FIG. 4A, the scintillation light, which is converted by the scintillator 4 enters from a positive side of the active matrix substrate 1 in the Z-axis direction. Note that, in the following description, the positive side in the Z-axis direction and a negative side in the Z-axis direction are referred to as an upper side and a lower side, respectively, in some cases.

As illustrated in FIG. 4A, the gate electrode 13a and a gate insulating film 102 are formed on a substrate 101.

The substrate 101 is a substrate having insulating property, an is formed of, for example, a glass substrate.

In this example, the gate electrode 13a is formed of the same material as that of the gate wiring lines 11 (see FIG. 3), and the gate electrode 13a and the gate wiring lines 11 have a structure in which a metal film formed of aluminum (Al) and a metal film formed of molybdenum nitride (MoN) are layered, for example. The thickness of the film formed of aluminum (Al) and the thickness of the film formed of molybdenum nitride (MoN) are approximately 300 nm and approximate 100 nm, respectively. Note that, the material and the thickness of the gate electrode 13a and the gate wiring lines 11 are not limited thereto.

The gate insulating film 102 covers the gate electrode 13a. For example, silicon oxide (SiOx), silicon nitride (SiNx), silicon nitride oxide (SiOxNy) (x>y), and silicon oxide nitride (SiNxOy) (x>y) may be used for the gate insulating film 102. In the present embodiment, the gate insulating film 102 has a structure in which an insulating film formed of silicon oxide (SiOx) as an upper layer and an insulating film formed of silicon nitride (SiNx) as a lower layer are layered. The thickness of the layer formed of silicon oxide (SiOx) and the thickness of the layer formed of silicon nitride (SiNx) are approximately 50 nm and approximately 400 nm, respectively. However, the material and the thickness of the gate insulating film 102 are not limited thereto.

The semiconductor active layer 13b, the source electrode 13c and the drain electrode 13d that are connected to the semiconductor active layer 13b are provided on the gate electrode 13a through intermediation of the gate insulating film 102.

The semiconductor active layer 13b is formed to in contact with the gate insulating film 102. The semiconductor active layer 13b is formed of an oxide semiconductor. For example, InGaO₃ (ZnO)₅, magnesium zinc oxide (MgxZn₁-xO), cadmium zinc oxide (CdxZn₁-xO), cadmium oxide (CdO), or an amorphous oxide semiconductor containing indium (In), gallium (Ga) gallium (Ga), and zinc (Zn) with a predetermined ratio may be used for the oxide semiconductor. In this example, the semiconductor active layer 13b is formed of an amorphous oxide semiconductor containing indium (In), gallium (Ga), and zinc (Zn) with a predetermined ratio. The thickness of the semiconductor active layer 13b is approximately 70 nm. Note that, the material and the thickness of the semiconductor active layer 13b are not limited thereto.

The source electrode 13c and the drain electrode 13d are arranged to be in contact with a part of the semiconductor active layer 13b on the gate insulating film 102. The drain electrode 13d is connected to the lower electrode 14a through the contact hole CH1.

In this example, the source electrode 13c and the drain electrode 13d are formed of the same material as that of the source wiring lines 10, and has a three-layer structure in which a metal film formed of molybdenum nitride (MoN), a metal film formed of aluminum (Al), and a metal film formed of molybdenum nitride (MoN) are layered, for example. The thicknesses of those three films are approximately 50 nm, 500 nm, and 100 nm, respectively, in the order from the lower layer side. However, the material and the thickness of the source electrode 13c and the drain electrode 13d are not limited thereto.

A first insulating film 103 is provided to overlap with the source electrode 13c and the drain electrode 13d on the gate insulating film 102. The first insulating film 103 includes an opening above the drain electrode 13d. The first insulating film 103 is formed of, for example, an inorganic insulating film formed of silicon nitride (SiN).

A second insulating film 104 is provided on the first insulating film 103. The second insulating film 104 includes an opening above the drain electrode 13d, and the contact hole CH1 is formed with the opening of the first insulating film 103 and the opening of the second insulating film 104.

The second insulating film 104 is formed of, for example, an organic transparent resin such as an acrylic resin and a siloxane resin, and the thickness thereof is approximately 2.5 μm. Note that, the material and the thickness of the second insulating film 104 are not limited thereto.

The lower electrode 14a is provided on the second insulating film 104, and the lower electrode 14a and the drain electrode 13d are connected to each other through the contact hole CH1. The lower electrode 14a is formed of, for example, a metal film containing molybdenum nitride (MoN), and the thickness is approximately 200 nm. Note that, the material and the thickness of the lower electrode 14a are not limited thereto.

The photoelectric conversion layer 15 is provided on the lower electrode 14a. The photoelectric conversion layer 15 is formed by sequentially layering an n-type amorphous semiconductor layer 151, an intrinsic amorphous semiconductor layer 152, a p-type amorphous semiconductor layer 153.

In the present embodiment, the length of the photoelectric conversion layer 15 in the X-axis direction is smaller than the length of the lower electrode 14a in the X-axis direction. That is, the lower electrode 14a protrudes to the outer side of the photoelectric conversion layer 15 over the side surface of the photoelectric conversion layer 15. Note that, a relationship between the length of the photoelectric conversion layer 15 and the length of the lower electrode 14a in the X-axis direction is not limited thereto. The length of the photoelectric conversion layer 15 and the length of the lower electrode 14a in the X-axis direction may be equivalent to each other.

The n-type amorphous semiconductor layer 151 is formed of amorphous silicon doped with an n-type impurity (such as phosphorus). The n-type amorphous semiconductor layer 151 is in contact with the lower electrode 14a.

The intrinsic amorphous semiconductor layer 152 is formed of intrinsic amorphous silicon. The intrinsic amorphous semiconductor layer 152 is in contact with the n-type amorphous semiconductor layer 151.

The p-type amorphous semiconductor layer 153 is formed of amorphous silicon doped with a p-type impurity (such as boron). The p-type amorphous semiconductor layer 153 is in contact with the intrinsic amorphous semiconductor layer 152.

In this example, the thickness of the n-type amorphous semiconductor layer 151, the thickness of the intrinsic amorphous semiconductor layer 152, and the thickness of the p-type amorphous semiconductor layer 153 are approximately 30 nm, approximately 1000 nm, and approximately 5 nm, respectively. Note that, the materials used for those semiconductor layers and the thicknesses are not limited thereto.

On the second insulating film 104, a third insulating film 105a is provided to include an opening at a position of overlapping with the photoelectric conversion layer 15 in a plan view and to cover the side surface of the photoelectric conversion layer 15. The third insulating film 105a is provided continuously to the adjacent pixel P1 on the second insulating film 104. The third insulating film 105a is formed of, for example, an inorganic insulating film formed of silicon nitride (SiN), and the thickness is approximately 300 nm. Note that, the material and the thickness of the third insulating film 105a are not limited thereto.

On the photoelectric conversion layer 15, the upper electrode 14b, which is in contact with the surface of the p-type amorphous semiconductor layer 153 and covers a part of the third insulating film 105a, is provided. Here, with reference to FIG. 4B, specific description is provided on the configuration of the upper electrode 14b. FIG. 4B is a cross-sectional view obtained by enlarging a part of configuration including the upper electrode 14b illustrated in FIG. 4A.

As illustrated in FIG. 4B, the upper electrode 14b includes an extending section 140b, which covers the surface of the p-type amorphous semiconductor layer 153 in an opening H1 of the third insulating film 105a on the photoelectric conversion layer 15 and covers the side surface of the photoelectric conversion layer 15 through intermediation of the third insulating film 105a. That is, in the present embodiment, the upper electrode 14b is arranged continuously on the third insulating film 105a that covers the top surface of the photoelectric conversion layer 15 and the side surface of the photoelectric conversion layer 15. In this example, the extending section 140b of the upper electrode 14b is not arranged continuously to the adjacent pixel P1.

For example, the upper electrode 14b is formed of a transparent conductive film formed of, Indium Tin Oxide (ITO), Indium Zn Oxide (IZO), or the like. The thickness of the upper electrode 14b is approximately 70 nm. Note that, the material and the thickness of the upper electrode 14b are not limited thereto.

A fourth insulating film 106, which covers the upper electrode 14b and the third insulating film 105a, is arranged on the upper electrode 14b. The fourth insulating film 106 includes the contact hole CH2 at the position of overlapping with the photodiode 12 in a plan view. The fourth insulating film 106 is formed of, for example, an organic transparent resin formed of an acrylic resin or a siloxane resin, and the thickness is, for example, approximately, 2.5 μm. Note that, the material and the thickness of the fourth insulating film 106 are not limited thereto.

The bias wiring line 16 and the transparent conductive film 17 connected to the bias wiring line 16 are provided on the fourth insulating film 106. The transparent conductive film 17 is in contact with the upper electrode 14b in the contact hole CH2.

The bias wiring line 16 is connected to the controller 2 (see FIG. 1). The bias wiring line 16 applies a bias voltage, which is input from the controller 2, to the upper electrode 14b through the contact hole CH2.

The bias wiring line 16 has a layered structure in which a metal film formed of titanium (Ti), a metal film formed of aluminum (Al), and a metal film formed of molybdenum nitride (MoN) are layered in the order from the lower layer side. The thickness of the film formed of titanium (Ti), the thickness of the film formed of aluminum (Al), and the thickness of the film formed of molybdenum nitride (MoN) are approximately 50 nm, approximately 300 nm, and approximately 100 nm, respectively. However, the material and the thickness of the bias wiring line 16 are not limited thereto.

The transparent conductive film 17 is formed of, for example, ITO, and the thickness is approximately 70 nm. Note that, the material and the thickness of the transparent conductive film 17 are not limited thereto.

On the fourth insulating film 106, a fifth insulating film 107 is provided to cover the transparent conductive film 17. The fifth insulating film 107 is formed of, for example, an inorganic insulating film formed of silicon nitride (SiN), and the thickness is, for example, approximately 450 nm. Note that, the material and the thickness of the fifth insulating film 107 are not limited thereto.

A sixth insulating film 108, which covers the fifth insulating film 107, is provided on the fifth insulating film 107. The sixth insulating film 108 is formed of, for example, an organic transparent resin formed of an acrylic resin or a siloxane resin, and the thickness is, for example, approximately 2.0 μm. Note that, the material and the thickness of the sixth insulating film 108 are not limited thereto.

As described above, the third insulating film 105a arranged on the side surface of the photoelectric conversion layer 15 is less likely to have a uniform thickness and is more liable to be discontinuous than the third insulating film 105a arranged on the second insulating film 104. In the above-described embodiment, the side surface of the photoelectric conversion layer 15 is covered with the extending section 140b of the upper electrode 14b through intermediation of the third insulating film 105a. Thus, even in a case where moisture penetrates the fourth insulating film 106, the moisture is less liable to enter the discontinuous part of the third insulating film 105a, and a leakage current of the photoelectric conversion layer 15 is less liable to flow.

### Manufacturing Method of Active Matrix Substrate 1

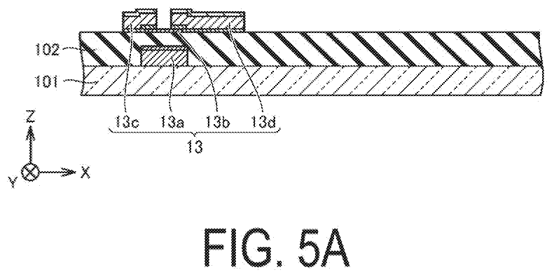

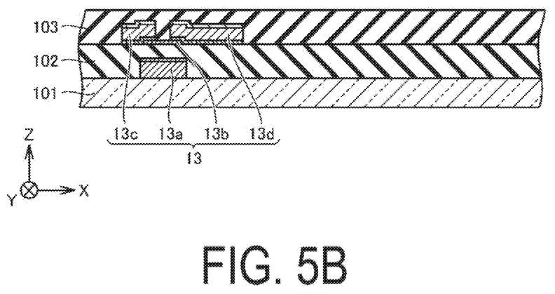

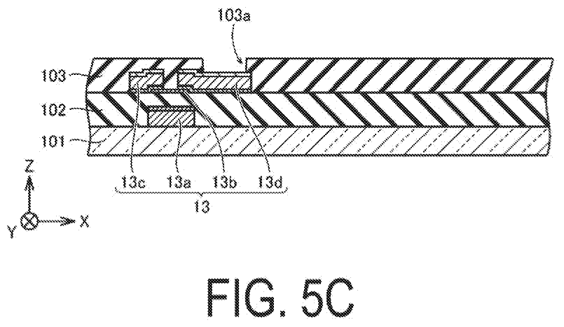

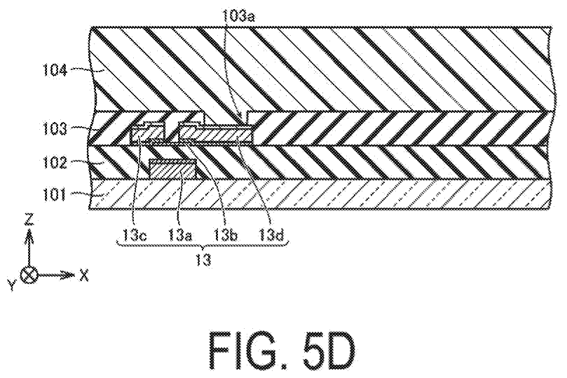

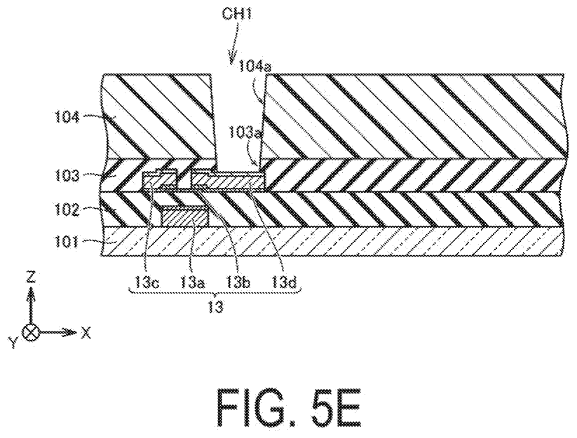

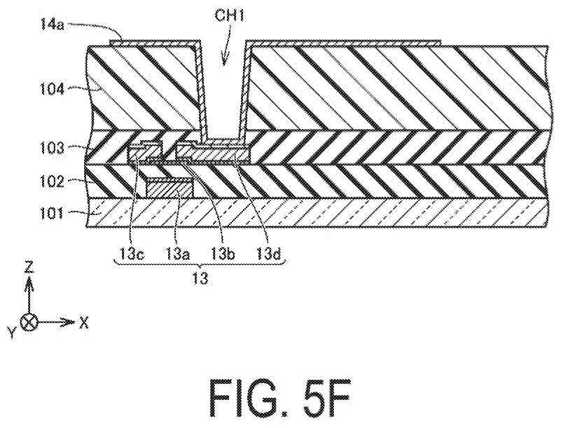

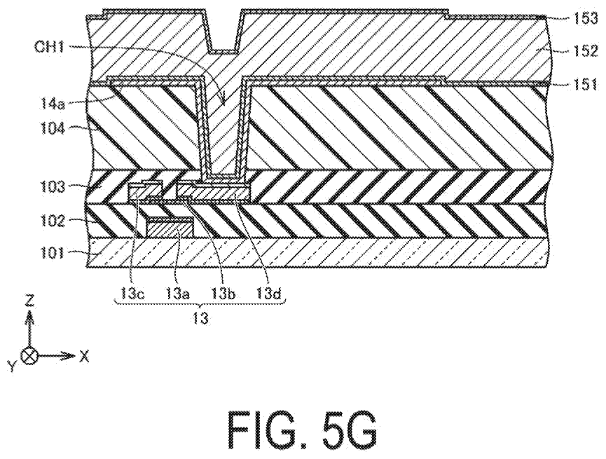

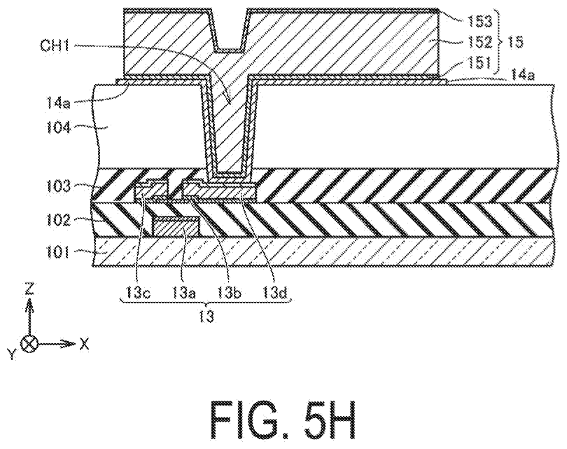

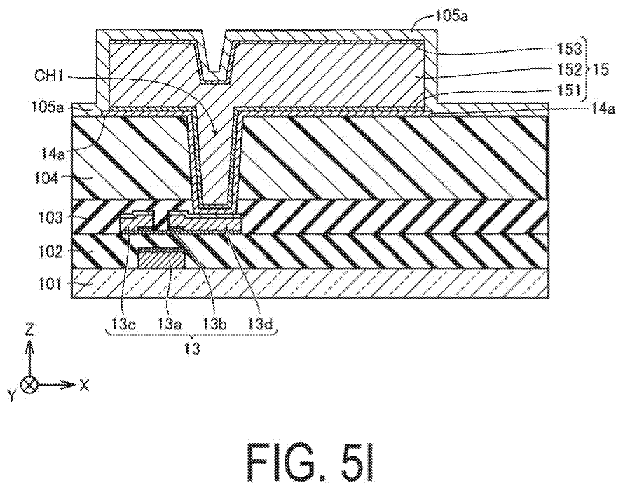

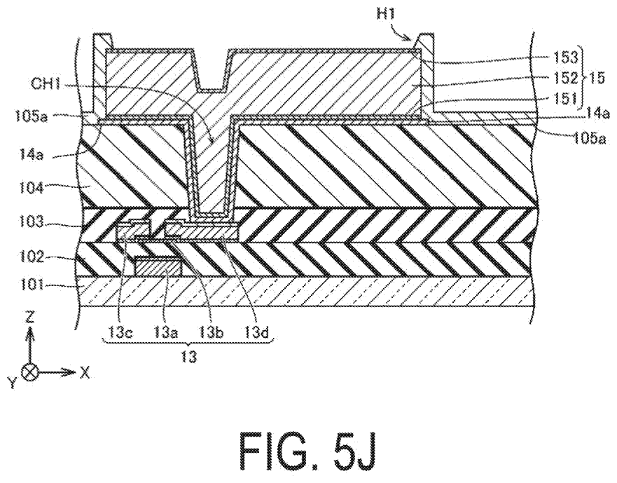

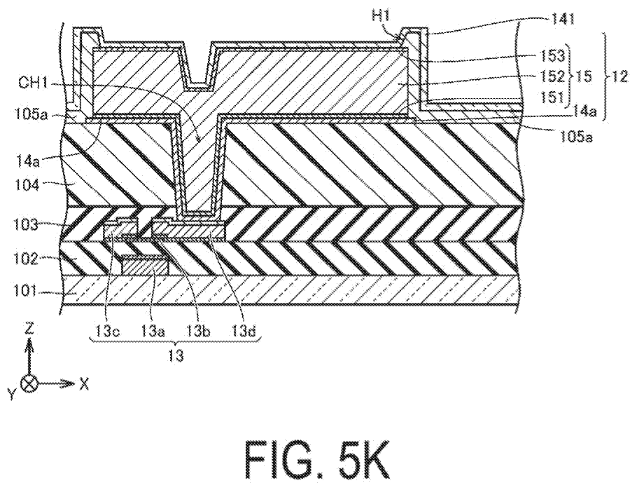

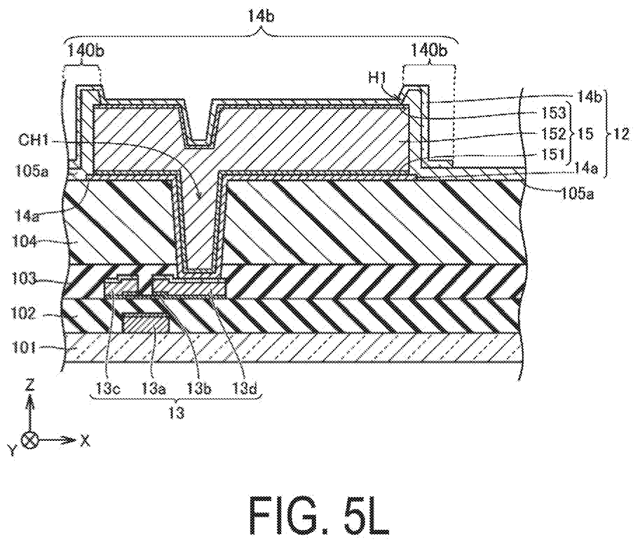

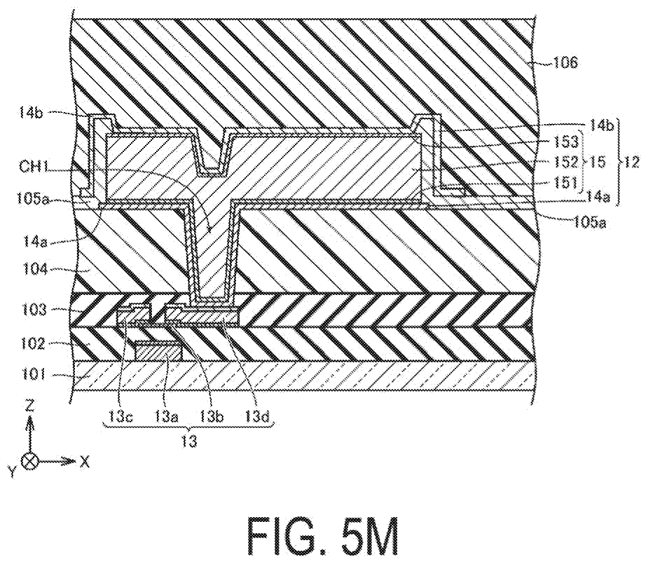

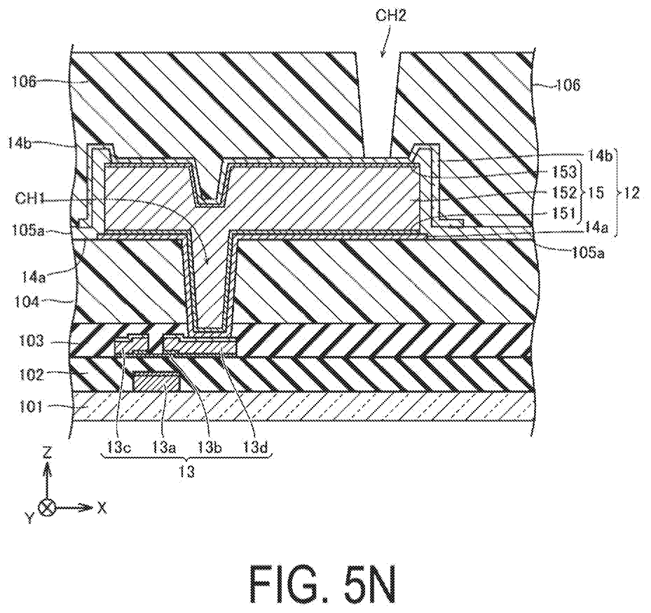

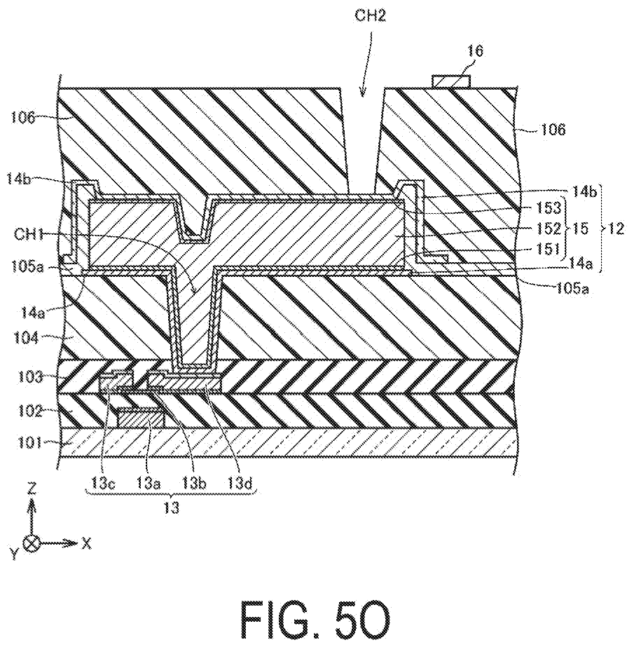

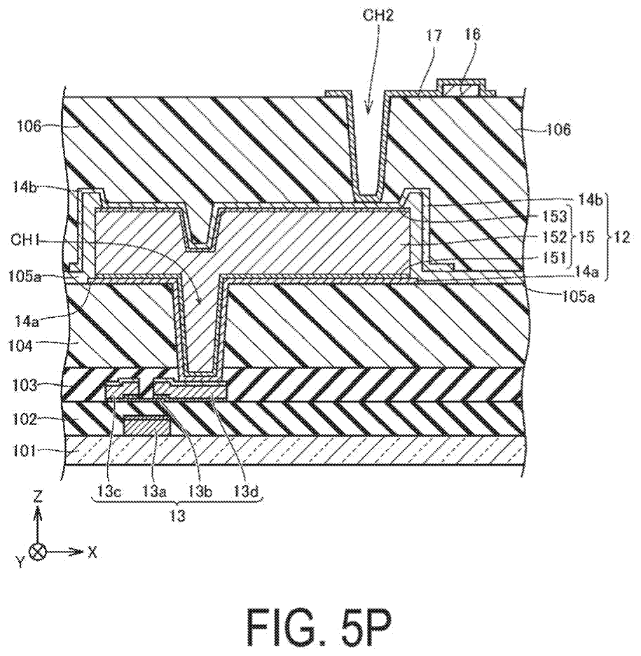

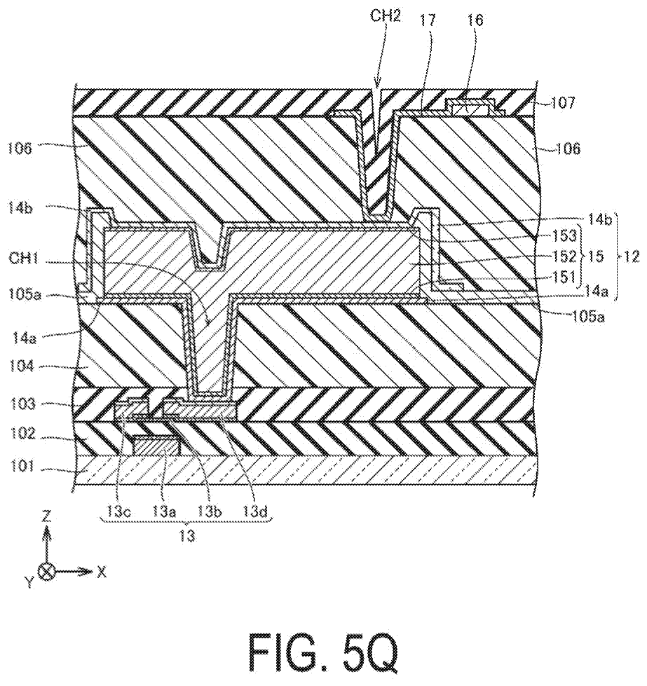

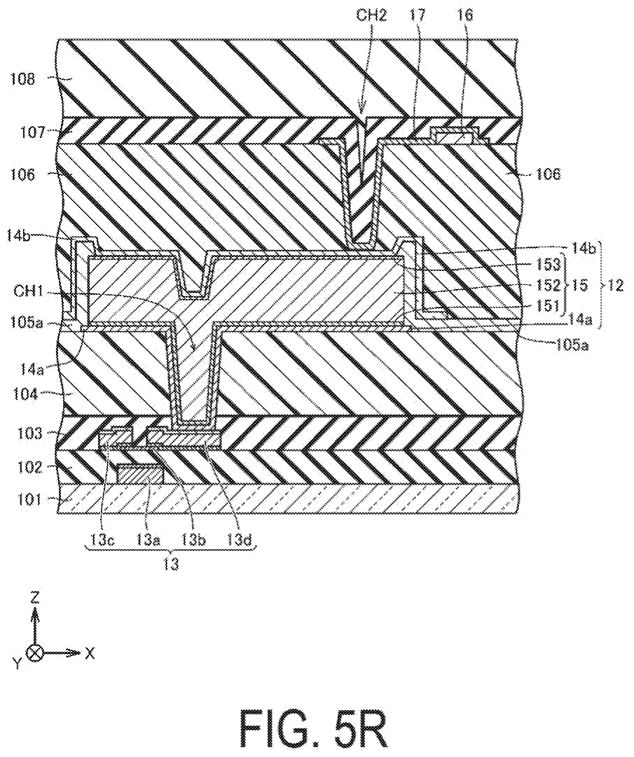

Next, with reference to FIGS. 5A to 5T, description is provided on a manufacturing method of the active matrix substrate 1. Each of FIGS. 5A to 5T is a cross-sectional view (cross section taken along the line A-A in FIG. 3) illustrating a manufacturing process of the pixel P1 of the active matrix substrate 1.

As illustrated in FIG. 5A, the gate insulating film 102 and the TFT 13 are formed on the substrate 101 by a known method.

Subsequently, for example, by the plasma CVD method, the first insulating film 103 formed of silicon nitride (SiN) is formed (see FIG. 5B).

After that, the entire surface of the substrate 101 is subjected to heat treatment at approximately 350° C., photolithography and dry etching using fluorine gas are performed, and the first insulating film 103 is patterned (see FIG. 5C). In this manner, an opening 103a of the first insulating film 103 is formed above the drain electrode 13d.

Next, for example, by slit coating, the second insulating film 104 formed of an acrylic resin or a siloxane resin is formed on the first insulating film 103 (see FIG. 5D). After that, by photolithography, the second insulating film 104 is patterned (see FIG. 5E). In this manner, an opening 104a of the second insulating film 104, which overlaps with the opening 103a in a plan view is formed, and the contact hole CH1 formed of the openings 103a and 104a is formed.

Subsequently, for example, by sputtering, a metal film formed of molybdenum nitride (MoN) is formed, photolithography and wet etching are performed to pattern the metal film. In this manner, the lower electrode 14a connected to the drain electrode 13d through the contact hole CH1 is formed on the second insulating film 104 (see FIG. 5F).

Next, for example, by the plasma CVD method, the n-type amorphous semiconductor layer 151, the intrinsic amorphous semiconductor layer 152, and the p-type amorphous semiconductor layer 153 are formed in the stated order (see FIG. 5G). Subsequently, photolithography and dry etching are performed to pattern the n-type amorphous semiconductor layer 151, the intrinsic amorphous semiconductor layer 152, and the p-type amorphous semiconductor layer 153 (see FIG. 5H). In this manner, the photoelectric conversion layer 15, which has a length in the X-axis direction shorter than the lower electrode 14a in a plan view, is formed.

Subsequently, for example, by the plasma CVD method, the third insulating film 105a formed of silicon nitride (SiN) is formed to cover the photoelectric conversion layer 15 and the surface of the lower electrode 14a, on the second insulating film 104 (see FIG. 5I). After that, photolithography and dry etching are performed to pattern the third insulating film 105a (see FIG. 5J). In this manner, the third insulating film 105a, which includes the opening H1 above the p-type amorphous semiconductor layer 153 of the photoelectric conversion layer 15 and covers a part on the p-type amorphous semiconductor layer 153 and the side surface of the photoelectric conversion layer 15, is formed on the second insulating film 104.

Next, for example, by sputtering, a transparent conductive film 141 formed of ITO is formed to cover the p-type amorphous semiconductor layer 153 and the third insulating film 105a (see FIG. 5K). Subsequently, photolithography and dry etching are performed to pattern the transparent conductive film 141. In this manner, the upper electrode 14b, which is provided on the surface of the p-type amorphous semiconductor layer 153 in the opening H1 and includes the extending section 140b covering the side surface of the photoelectric conversion layer 15 through intermediation of the third insulating film 105a, is formed (see FIG. 5L).

Subsequently, for example, by slit coating, the fourth insulating film 106 formed of an acrylic resin or a siloxane resin is formed (see FIG. 5M). After that, by photolithography, the fourth insulating film 106 is patterned to form the contact hole CH2 (see FIG. 5N).

Next, for example, by sputtering, a metal film in which titanium (Ti), aluminum (Al), and molybdenum nitride (MoN) are sequentially layered is formed, and photolithography and wet etching are performed to pattern the metal film. With this, the bias wiring line 16 is formed on the fourth insulating film 106 at a position of not overlapping with the photodiode 12 in a plan view (see FIG. 5O).

Next, for example, by sputtering, a transparent conductive film formed of ITO is formed on the fourth insulating film 106, photolithography and dry etching are performed to pattern the transparent conductive film. With this, the transparent conductive film 17 is formed (see FIG. 5P). The transparent conductive film 17 is connected to the bias wiring line 16, and is connected to the upper electrode 14b through the contact hole CH2.

Subsequently, for example, by the plasma CVD method, the fifth insulating film 107 formed of silicon nitride (SiN) is formed to cover the transparent conductive film 17, on the fourth insulating film 106 (see FIG. 5Q).

After that, for example, by slit coating, the sixth insulating film 108 formed of an acrylic resin or a siloxane resin is formed to cover the fifth insulating film 107 (see FIG. 5R). In this manner, the active matrix substrate 1 according to the present embodiment is manufactured.

In the above-described step in FIG. 5I, in a case where the third insulating film 105a is formed by the plasma CVD method, a speed at which the third insulating film 105a is formed is liable to differ between the third insulating film 105a formed on the side surface of the photoelectric conversion layer 15 and the third insulating film 105a formed on the second insulating film 104. Furthermore, the third insulating film 105a formed on the side surface of the photoelectric conversion layer 15 is liable to be discontinuous. However, in the above-described embodiment, in the step in FIG. 5K, the side surface of the photoelectric conversion layer 15 are covered with the extending section 140b of the upper electrode 14b through intermediation of the third insulating film 105a. Thus, even in a case where moisture penetrates the fourth insulating film 106, the moisture is less liable to enter the discontinuous part of the third insulating film 105a, and a leakage current is less liable to flow.

Operation of X-ray Imaging Device 100

Here, description is provided on an operation of the X-ray imaging device 100 illustrated in FIG. 1. First, an X-ray is emitted from the X-ray source 3. At this time, the controller 2 applies a predetermined voltage (bias voltage) to the bias wiring line 16 (see FIG. 3 and the like). The X-ray emitted from the X-ray source 3 passes through the subject S, and enters the scintillator 4. The X-ray having entered the scintillator 4 is converted into fluorescence (scintillation light), and the scintillation light enters the active matrix substrate 1. In a case where the scintillation light enters the photodiode 12 to which each of the pixels P1 is provided on the active matrix substrate 1, the photodiode 12 converts the scintillation light into an electric charge depending on an amount of the scintillation light. A signal corresponding to the electric charge converted by the photodiode 12 is read by the signal reading section 2B (see FIG. 2 and the like) via the source wiring line 10 in a case where the TFT 13 (see FIG. 3 and the like) is in the on state depending on a gate voltage (positive voltage) output from the gate control section 2A via the gate wiring line 11. Then, an X-ray image depending on the read signals is generated by the controller 2.

### Second Embodiment

In the first embodiment described above, the example in which the upper electrode 14b is covered with the fourth insulating film 106 is given. However, an inorganic insulating film covering the upper electrode 14b may be provided between the upper electrode 14b and the fourth insulating film 106.

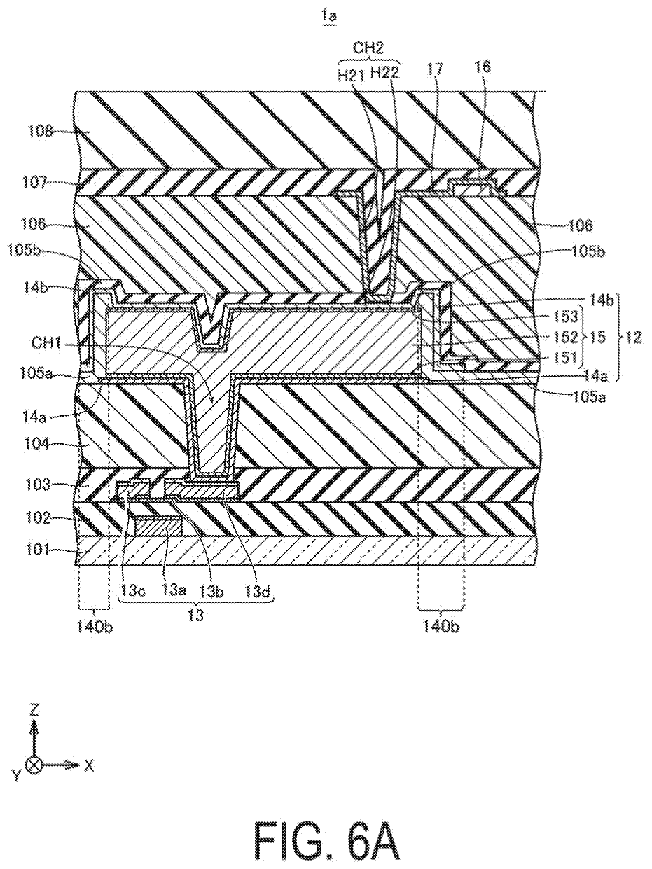

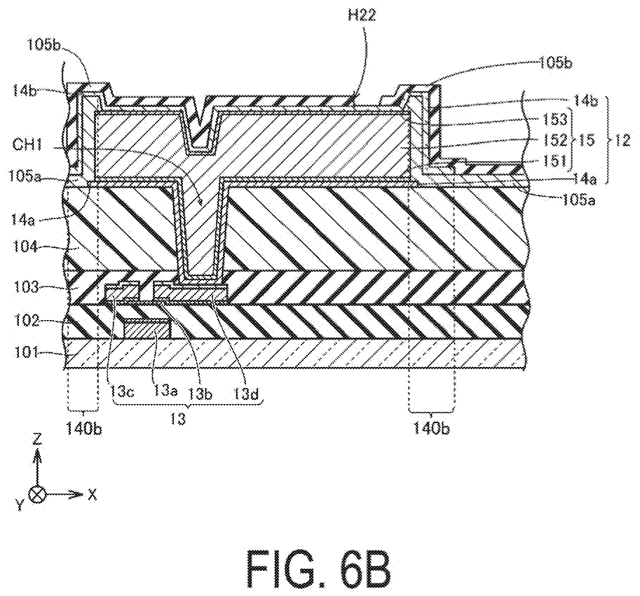

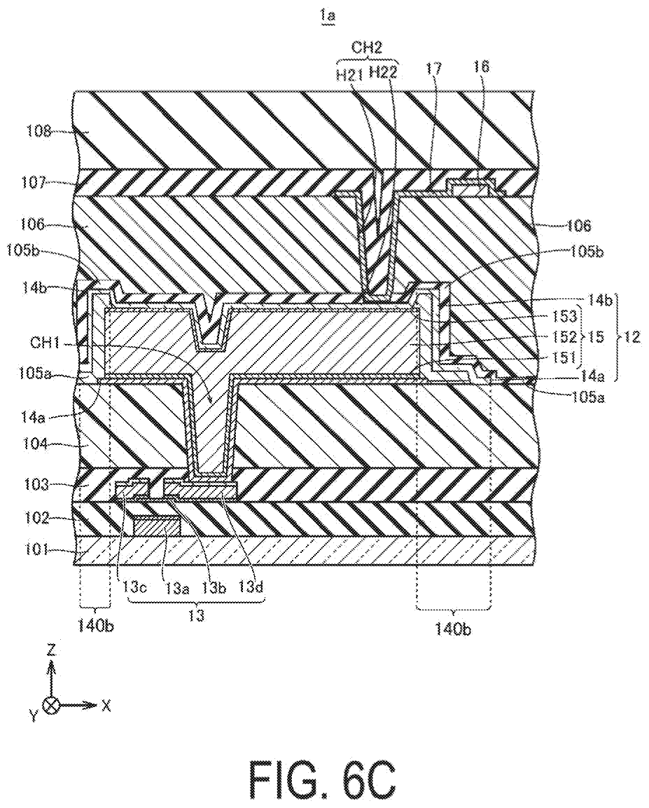

FIG. 6A is a cross-sectional view of an outline of a pixel of an active matrix substrate 1a according to the present embodiment. Note that, in FIG. 6A, the same configurations as those in the first embodiment are denoted with the same reference signs as those in the first embodiment. Now, a configuration different from that in the first embodiment is described.

As illustrated in FIG. 6A, the active matrix substrate 1a according to the present embodiment includes an inorganic insulating film 105b covering the surface of the upper electrode 14b. The inorganic insulating film 105b is formed of, for example, silicon oxide (SiO₂) or silicon nitride (SiN). The inorganic insulating film 105b includes an opening H22 above the upper electrode 14b.

The fourth insulating film 106 covers the inorganic insulating film 105b, and an opening H21 of the fourth insulating film 106 overlaps with the opening H22 of the inorganic insulating film 105b in a plan view. In the present embodiment, the contact hole CH2 is formed with the openings H21 and H22.

As described above, the upper electrode 14b is covered with the inorganic insulating film 105b. With this, the side surface of the photoelectric conversion layer 15 is covered with the third insulating film 105a, the extending section 140b of the upper electrode 14b, and the inorganic insulating film 105b. Thus, compared to the first embodiment, even in a case where moisture penetrates the fourth insulating film 106, the moisture is less liable to enter the discontinuous part of the third insulating film 105a on the side surface of the photoelectric conversion layer 15. Therefore, compared to the first embodiment, the present configuration can cause a leakage current of the photoelectric conversion layer 15 to be less liable to flow and improve detection accuracy of an X-ray.

Note that, the active matrix substrate 1a according to the present embodiment may be manufactured in the following manner. First, the above-described steps illustrated in FIG. 5A to FIG. 5L are performed. After that, for example, by the plasma CVD method, the inorganic insulating film 105b formed of silicon nitride (SiN) is formed to cover the upper electrode 14b, photolithography and dry etching are performed to pattern the inorganic insulating film 105b, and the opening H22 is formed above the upper electrode 14b (see FIG. 6B). Subsequently, by performing the above-described steps in FIGS. 5M to 5R, the active matrix substrate 1a illustrated in FIG. 6A is formed.

Note that, in the example in FIG. 6A, the third insulating film 105a is provided continuously to the adjacent pixel P1, and the end portions of the third insulating film 105a are not covered with the extending section 140b of the upper electrode 14b. In contrast, as in the example illustrated in FIG. 6C, the third insulating film 105a may not be provided continuously to the adjacent pixel P1, and the end portions of the third insulating film 105a may be covered with the extending section 140b of the upper electrode 14b.

By covering the entire third insulating film 105a with the upper electrode 14b as described above, moisture is less liable to enter the discontinuous part of the third insulating film 105a and a leakage current of the photoelectric conversion layer 15 is liable to flow than the configuration in FIG. 6A.

### Third Embodiment

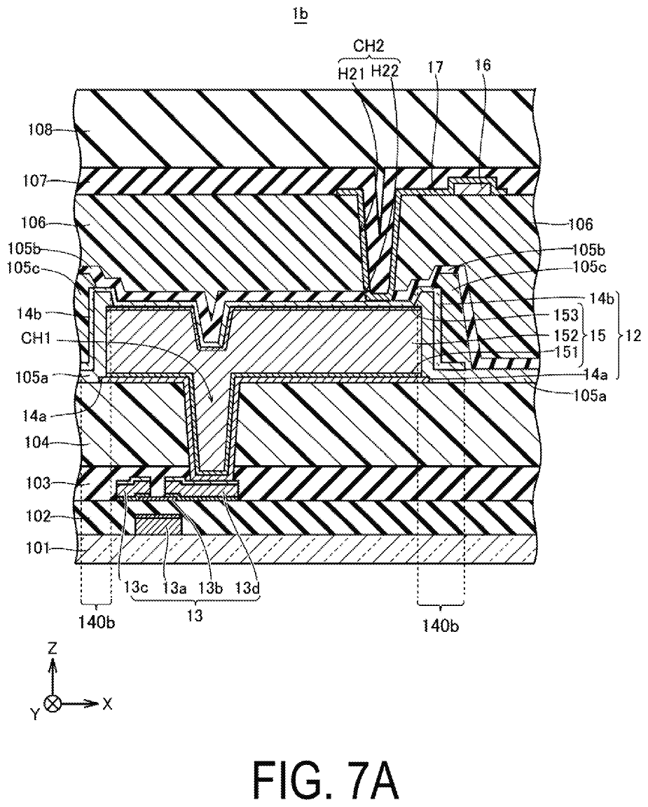

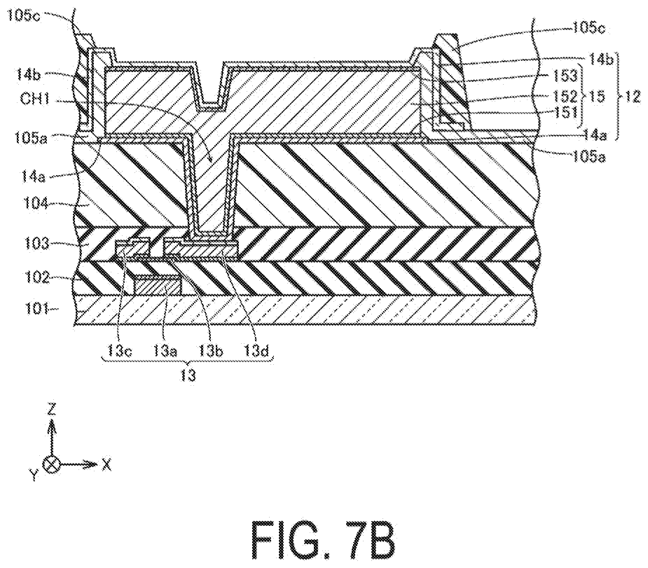

In the second embodiment described above, the example in which the third insulating film 105a, the extending section 140b of the upper electrode 14b, and the inorganic insulating film 105b are layered on the side surface of the photoelectric conversion layer 15 is given. However, the following configuration may be adopted. FIG. 7A is a cross-sectional view of an outline of a pixel being a part of an active matrix substrate 1b according to the present embodiment. In FIG. 7A, the same configurations as those in the second embodiment are denoted with the same reference signs as those in the second embodiment. Now, a configuration different from that in the second embodiment is described.

As illustrated in FIG. 7A, the active matrix substrate 1b includes a transparent resin film 105c covering the extending section 140b of the upper electrode 14b. The transparent resin film 105c covers the side surface of the photoelectric conversion layer 15 through intermediation of the third insulating film 105a and the extending section 140b. The transparent resin film 105c does not overlap with the photoelectric conversion layer 15 in a plan view.

The transparent resin film 105c may be, for example, an organic insulating film formed of an acrylic resin or a siloxane resin. It is preferred that thickness of the transparent resin film 105c be approximately 1.5 μm.

The inorganic insulating film 105b covers the third insulating film 105a, the upper electrode 14b, and the surface of the transparent resin film 105c.

In this manner, providing the transparent resin film 105c enhances an effect of preventing moisture penetration to the discontinuous part of the third insulating film 105a, and causes a leakage current to be less liable to flow than the configuration in the second embodiment.

The active matrix substrate 1b according to the present embodiment may be manufactured in the following manner. First, the above-described steps illustrated in FIGS. 5A to 5L are performed. After that, for example, by slit coating, a transparent resin film formed of an acrylic resin or a siloxane resin is formed. Then, patterning is performed by photolithography. In this manner, the transparent resin film 105c is formed on the upper electrode 14b overlapping with the third insulating film 105a covering the side surface of the photoelectric conversion layer 15 (see FIG. 7B). After that, the above-described steps in FIG. 6B and FIGS. 5M to 5R are performed, and thus the active matrix substrate 1b illustrated in FIG. 7A is formed.

### Other Configuration Example 1

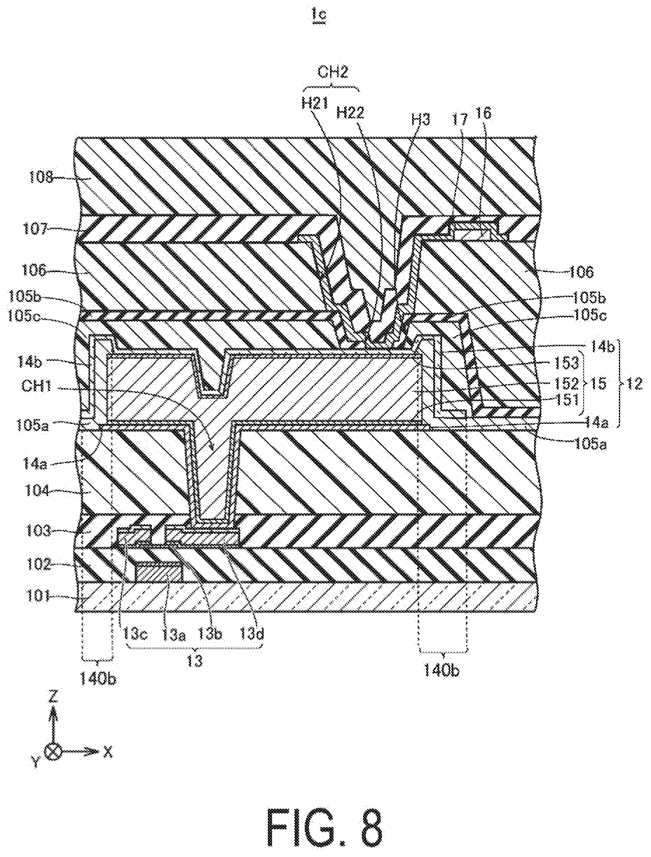

On the active matrix substrate 1b illustrated FIG. 7A described above, the transparent resin film 105c is formed on the extending section 140b of the upper electrode 14b, and the transparent resin film 105c is not formed on the upper electrode 14b covering the top surface of the photoelectric conversion layer 15. That is, on the active matrix substrate 1b illustrated in FIG. 7A, the transparent resin film 105c does not overlap with the photoelectric conversion layer 15 in a plan view. In contrast, in the present configuration, as illustrated in FIG. 8, the transparent resin film 105c is arranged to overlap with the photoelectric conversion layer 15 in a plan view.

On active matrix substrate 1c illustrated in FIG. 8, the transparent resin film 105c is arranged on the upper electrode 14b, which covers the top surface of the photoelectric conversion layer 15, and the extending section 140b. An opening H3 of the transparent resin film 105c is formed above the photoelectric conversion layer 15.

The inorganic insulating film 105b covers the transparent resin film 105c and the third insulating film 105a, to form the opening H22 on an inner side than the opening H3 of the transparent resin film 105c. The fourth insulating film 106 is arranged on the inorganic insulating film 105b, to form the opening H21 on an outer side with respect to the opening H22 of the inorganic insulating film 105b.

In the present configuration, a part of the upper electrode 14b on the top surface of the photoelectric conversion layer 15 is covered with the transparent resin film 105c. Thus, in a case where entry of moisture is from the inorganic insulating film 105b on the photoelectric conversion layer 15, the moisture is less liable to penetrate the discontinuous part of the third insulating film 105a on the side surface of the photoelectric conversion layer 15 and a leakage current is less liable to flow than the configuration in the third embodiment.

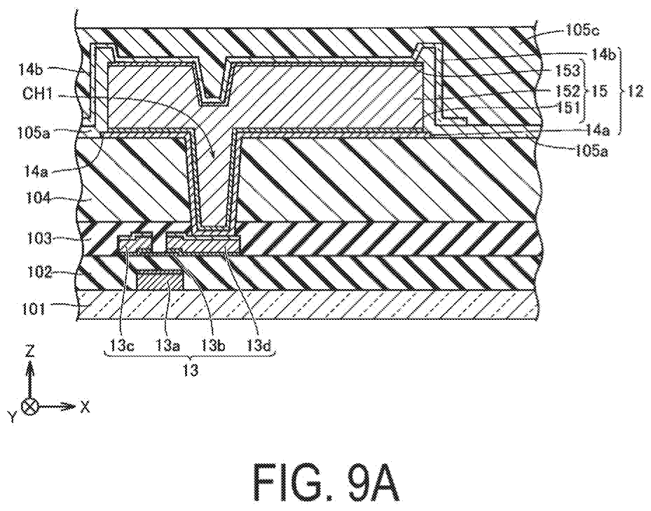

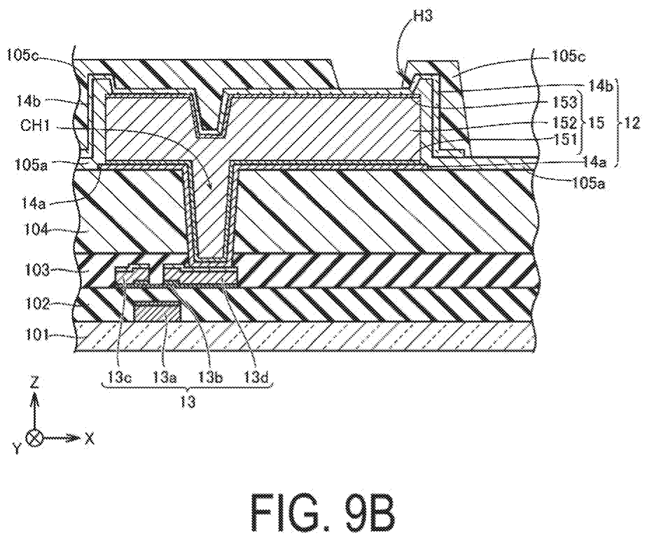

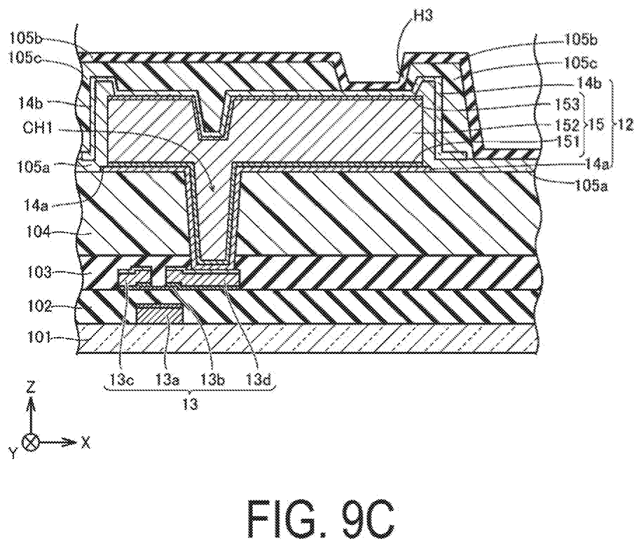

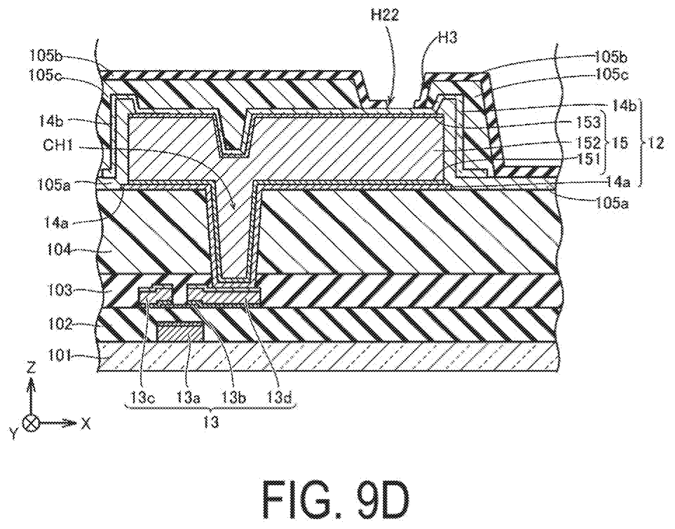

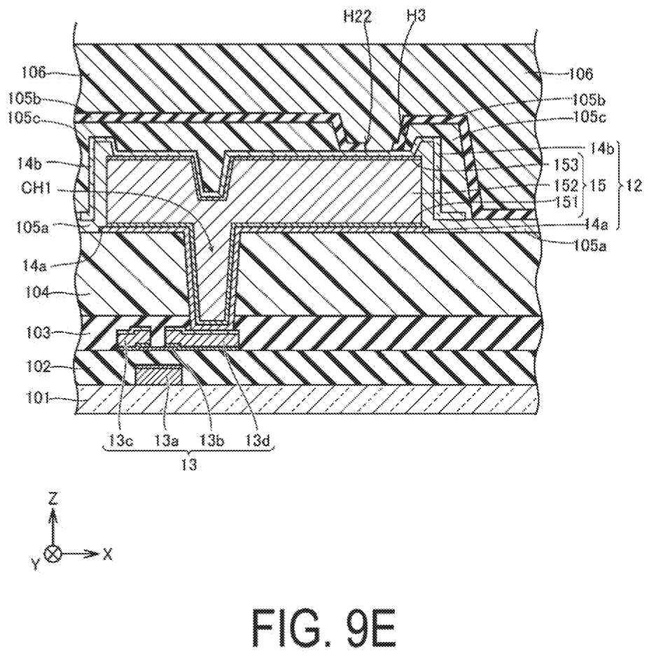

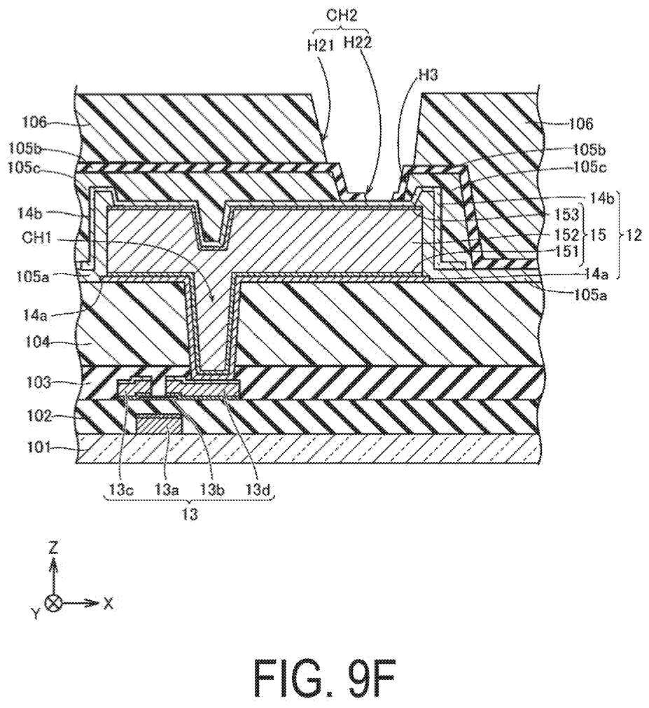

The active matrix substrate 1c in the present configuration may be manufactured in the following manner. First, the above-described steps in FIGS. 5A to 5L are performed. After that, by slit coating, the transparent resin film 105c formed of an acrylic resin or a siloxane resin is formed (see FIG. 9A). Then, by photolithography, the transparent resin film 105c is patterned. In this manner, the opening H3 is formed at a position of overlapping with the photoelectric conversion layer 15 in a plan view, and the transparent resin film 105c, which covers the entire upper electrode 14b arranged on the outer side with respect to the opening H3, is formed (see FIG. 9B).

After that, for example, by the plasma CVD method, the inorganic insulating film 105b formed of silicon nitride (SiN) is formed to cover the transparent resin film 105c (see FIG. 9C). Subsequently, photolithography and dry etching are performed to pattern the inorganic insulating film 105b. With this, the opening H22 is formed on the inner side of the opening H3 (see FIG. 9D).

Next, by slit coating, the fourth insulating film 106 formed of an acrylic resin or a siloxane resin is formed to cover the inorganic insulating film 105b (see FIG. 9E). Then, by photolithography, the fourth insulating film 106 is patterned, and the opening H21 of the fourth insulating film 106 is formed on the outer side with respect to the opening H22 (see FIG. 9F). After that, by performing the above-described steps in FIGS. 5O to 5R, the active matrix substrate 1c illustrated in FIG. 8 is manufactured.

### Other Configuration Example 2

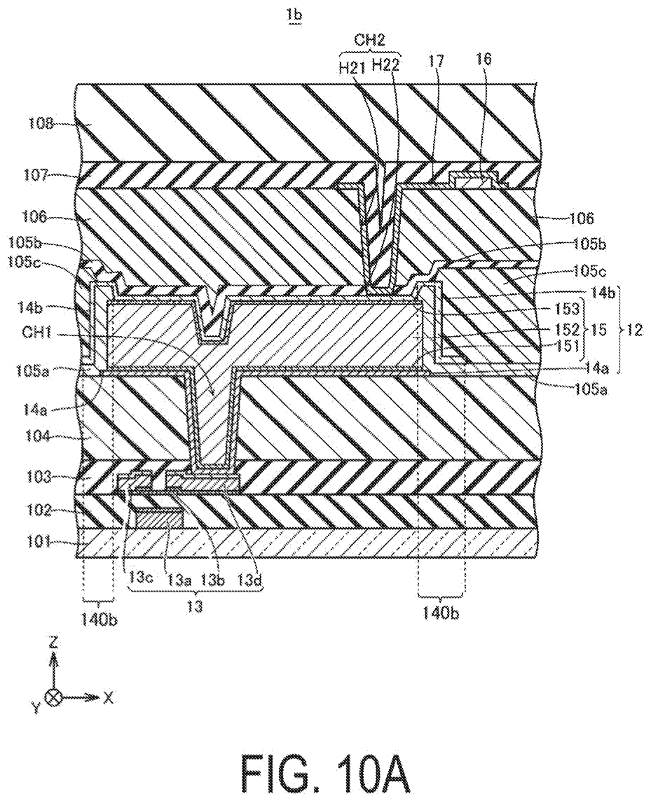

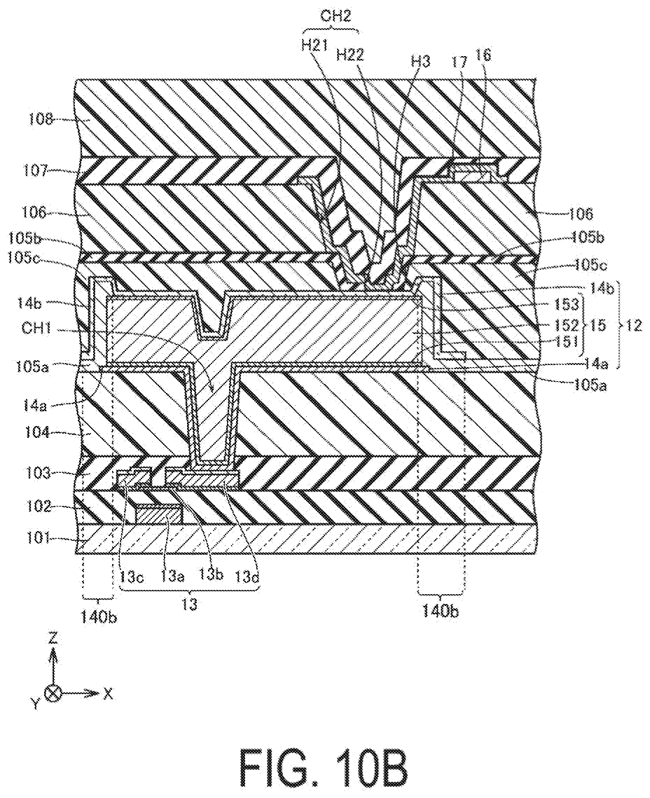

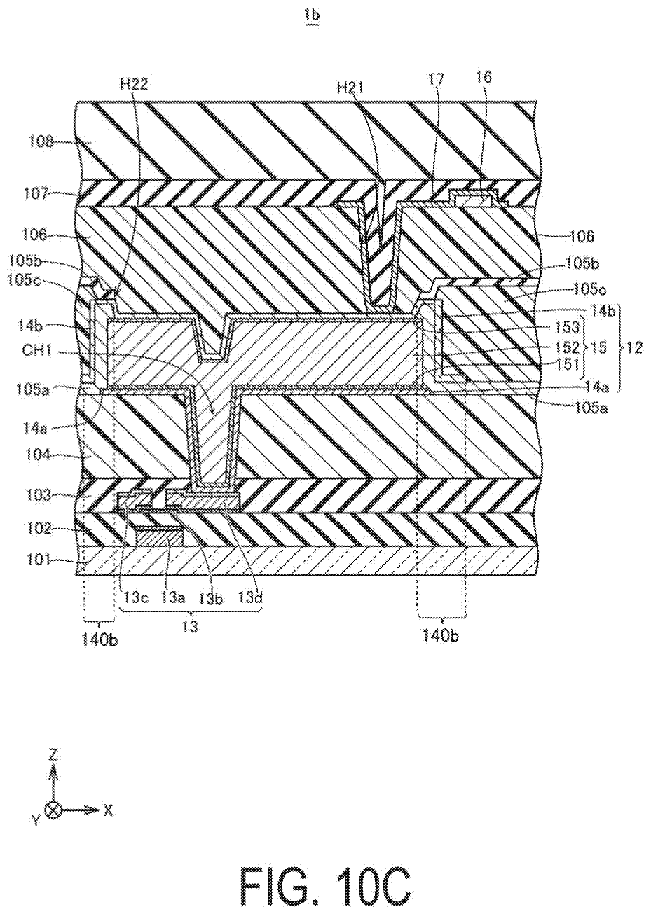

In the third embodiment and Other Configuration Example 1 described above, the transparent resin film 105c is not provided continuously to the adjacent pixel P1, but the transparent resin film 105c may be provided continuously to the adjacent pixel P1. That is, as illustrated in FIG. 10A, the transparent resin film 105c may cover the extending section 140b of the upper electrode 14b and may cover the entire surface of the third insulating film 105a. As illustrated in FIG. 10B, the transparent resin film 105c may cover a part of the upper electrode 14b on the top surface of the photoelectric conversion layer 15, the extending section 140b of the upper electrode 14b, and the entire surface of the third insulating film 105a.

In the configuration in FIGS. 10A and 10B, the transparent resin film 105c covers the entire surface of the third insulating film 105a. Thus, in the case where moisture penetrates the inorganic insulating film 105b, the moisture is less liable to enter the third insulating film 105a than the case in the third embodiment (see FIG. 7A) or Other Configuration Example 1 (see FIG. 8). As a result, an effect of preventing moisture penetration to the discontinuous part of the third insulating film 105a covering the side surface of the photoelectric conversion layer 15 is improved, and a leakage current is less liable to flow.

Note that, in the above-described configuration in FIG. 10A, the inorganic insulating film 105b is arranged on the upper electrode 14b covering the top surface of the photoelectric conversion layer 15, the inorganic insulating film 105b overlaps with the photoelectric conversion layer 15 in a plan view. However, as illustrated in FIG. 10C, the inorganic insulating film 105b may be arranged on the transparent resin film 105c at a position of not overlapping with the photoelectric conversion layer 15 in a plan view. Even in the case where such configuration is adopted, the inorganic insulating film 105b is arranged on the upper electrode 14b, to cover the surface of the transparent resin film 105c. Thus, moisture penetration to the discontinuous part of the third insulating film 105a covering the side surface of the photoelectric conversion layer 15 can be prevented. The inorganic insulating film 105b does not overlap with the photoelectric conversion layer 15 in a plan view, and this improves light entry efficiency of the photoelectric conversion layer 15, and improves quantum efficiency.

### Fourth Embodiment

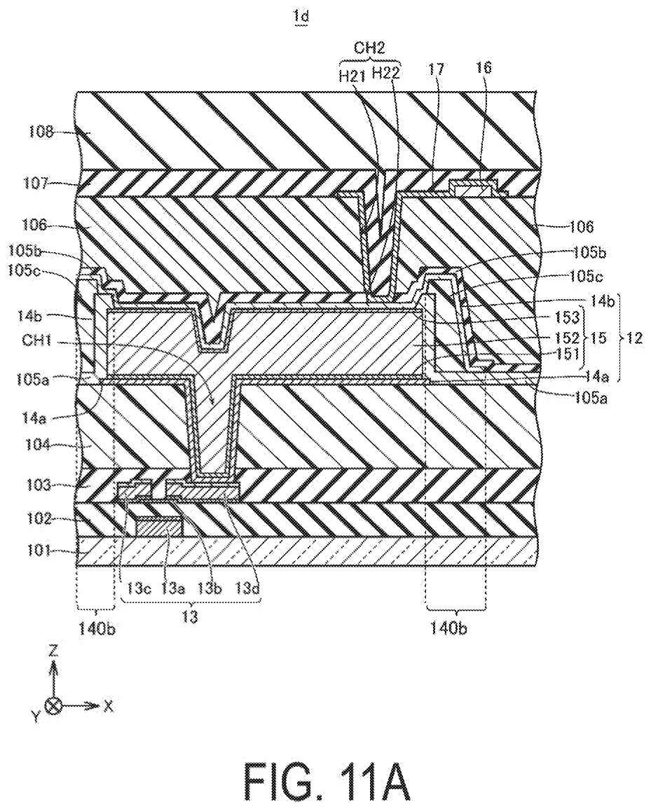

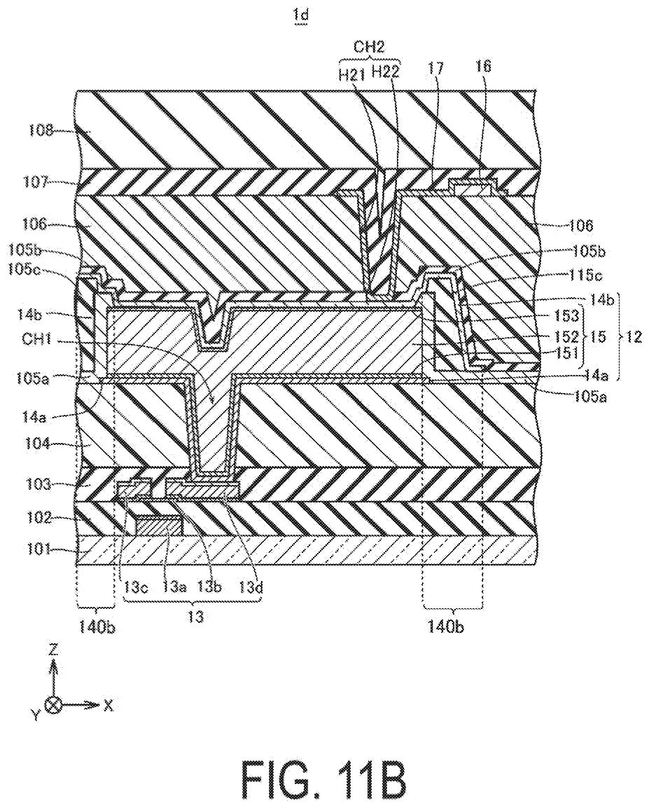

In the third embodiment described above, the third insulating film 105a covering the side surface of the photoelectric conversion layer 15 overlaps with the upper electrode 14b (see FIG. 7A and the like). However, the configuration as illustrated in FIG. 11A may be adopted. That is, as illustrated in FIG. 11A, the third insulating film 105a covering the side surface of the photoelectric conversion layer 15 may overlap with the transparent resin film 105c, and the extending section 140b of the upper electrode 14b may cover the transparent resin film 105c.

In the present embodiment, the transparent resin film 105c, the extending section 140b of the upper electrode 14b, the inorganic insulating film 105b are layered on the third insulating film 105a covering the side surface of the photoelectric conversion layer 15. The end portions of the upper electrode 14b are covered with the inorganic insulating film 105b. Thus, even in a case where moisture penetrates the fourth insulating film 106, the moisture is less liable to enter the discontinuous part of the third insulating film 105a on the side surface of the photoelectric conversion layer 15, and a leakage current is less liable to flow.

In a case where an active matrix substrate 1d according to the present embodiment is manufactured, the steps in FIGS. 5A to 5J described above are performed, and then, by slit coating, the transparent resin film 105c formed of an acrylic resin or a siloxane resin is formed. Then, by photolithography, the transparent resin film 105c is patterned (omitted in illustration). In this manner, the transparent resin film 105c, which covers the side surface of the photoelectric conversion layer 15 through intermediation of the third insulating film 105a, is formed. After that, steps similar to the above-described steps in FIGS. 5K to 5L, FIG. 6B, and FIGS. 5M to 5R are performed, and thus the active matrix substrate 1d illustrated in FIG. 11A is manufactured.

Note that, as illustrated in FIG. 11B, in place of the transparent resin film 105c on the active matrix substrate 1d in FIG. 11A, an inorganic insulating film 115c may be arranged. The inorganic insulating film 115c is penetrated by less moisture than the transparent resin film 105c. Thus, according to such configuration, in a case where moisture penetrates the fourth insulating film 106, the moisture is less liable to penetrate the discontinuous part of the third insulating film 105a on the side surface of the photoelectric conversion layer 15, and a leakage current of the photoelectric conversion layer 15 is less liable to flow.

The embodiments are described above, but the above-described embodiments are merely examples. Thus, the active matrix substrate and the imaging panel according to the disclosure are not limited to the above-described embodiments, and can be carried out by modifying the above-described embodiments as appropriate without departing from the scope of the disclosure. Now, other modified examples of the above-described embodiments are given.

### Modified Example 1

In the first embodiment described above, of the upper electrode 14b covering the photoelectric conversion layer 15, a part of the upper electrode 14b, which overlaps with the third insulating film 105a covering the side surface of the photoelectric conversion layer 15, may be covered with an inorganic insulating film.

That is, as illustrated in the drawing, on an active matrix substrate 1e in the present modified example, the extending section 140b of the upper electrode 14b is covered with an inorganic insulating film 125c. The inorganic insulating film 125c does not overlap with the photoelectric conversion layer 15 in a plan view. In this example, it is preferred that the inorganic insulating film 125c be formed of, for example, silicon nitride (SiN) and that the thickness be approximately 300 nm.

According to such configuration, in the case where moisture penetrates the fourth insulating film 106, the moisture is less liable to penetrate the discontinuous part of the third insulating film 105a on the side surface of the photoelectric conversion layer 15, and a leakage current is less liable to flow than the first embodiment.

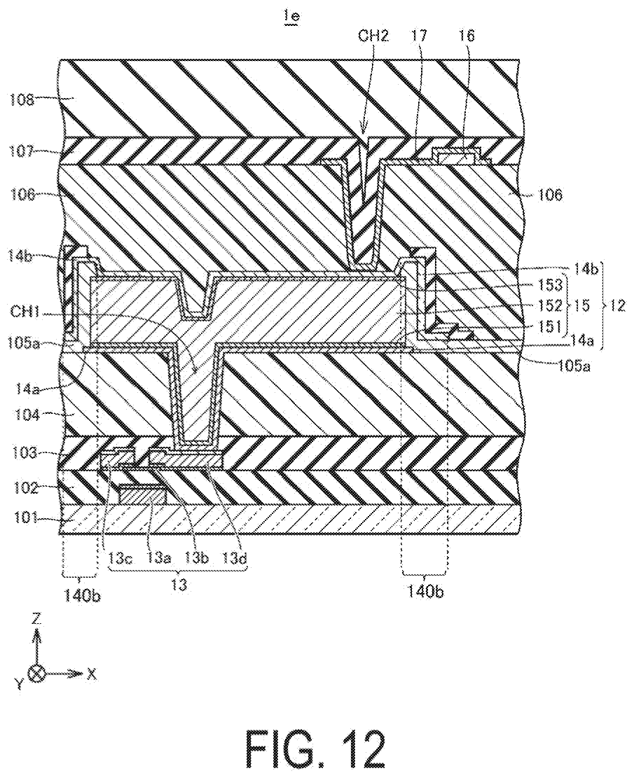

Note that, although omitted in illustration, in FIG. 12, the surface of the inorganic insulating film 125c may be covered with an inorganic insulating film formed of, for example, silicon nitride (SiN). It is preferred that the thickness of the inorganic insulating film be approximately 300 nm. By adopting such configuration, the third insulating film 105a, the extending section 140b of the upper electrode 14b, and the two inorganic insulating films are layered on the side surface of the photoelectric conversion layer 15. Thus, an effect of preventing moisture penetration to the discontinuous part of the third insulating film 105a is exerted more than the configuration in FIG. 12.

### Modified Example 2

In the first embodiment described above, the upper electrode 14b including the extending section 140b is formed continuously on the third insulating film 105a from the top surface of the photoelectric conversion layer 15 to the side surface of the photoelectric conversion layer 15, but may be configured as in the following.

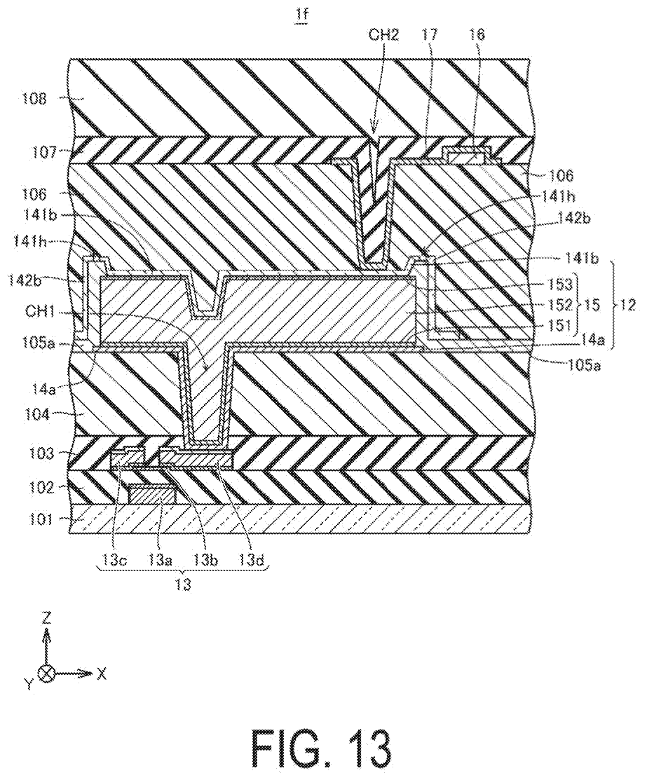

FIG. 13 is a cross-sectional view illustrating an outline configuration of a pixel of an active matrix substrate 1f in the present modified example. As illustrated in FIG. 13, on the active matrix substrate 1f, an upper electrode 141b is arranged on the top surface of the photoelectric conversion layer 15, and a conductive film 142b, which is formed of the same material as that of the upper electrode 141b and covers the side surface of the photoelectric conversion layer 15 through intermediation of the third insulating film 105a, is arranged. That is, the upper electrode 141b and the conductive film 142b are away from each other on the third insulating film 105a.

In the present modified example, the third insulating film 105a on the side surface of the photoelectric conversion layer 15 is covered with the conductive film 142b. Thus, similarly to the first embodiment, even in a case where moisture penetrates the fourth insulating film 106, the moisture is less liable to enter the discontinuous part of the third insulating film 105a, and a leakage current is less liable to flow.

The conductive film 142b can be manufactured simultaneously in the step of forming the upper electrode 141b. Specifically, in the above-described step in FIG. 5L, an opening 141h of a conductive film 141 is formed above the third insulating film 105a. The opening 141h is formed in the top surface portion of the third insulating film 105a covering the side surface of the photoelectric conversion layer 15. In this manner, the upper electrode 141b and the conductive film 142b are formed. Thus, the number of steps of manufacturing the active matrix substrate can be reduced compared to the case where the conductive film 142b is formed by using a material different from that of the upper electrode 141b.

Note that, although omitted in illustration, also in the other embodiments and modified examples other than the first embodiment similarly to the present modified example, there may be adopted a configuration of arranging the conductive film, which is arranged away from the part being the upper electrode on the top surface of the photoelectric conversion layer 15 and covers the side surface of the photoelectric conversion layer 15 through intermediation of the third insulating film 105a.

The following description can be made on the active matrix substrate, the imaging panel including the active matrix substrate, and the manufacturing method of the active matrix substrate that are described above.

An active matrix substrate according to a first configuration includes a photoelectric conversion element; an electrode provided on at least one main surface of the photoelectric conversion element; and a first inorganic film covering a side surface of the photoelectric conversion element, wherein the electrode includes an extending section covering the side surface of the photoelectric conversion element through intermediation of the first inorganic film.

According to the first configuration, the electrode is provided on at least one surface of the photoelectric conversion element, and the side surface of the photoelectric conversion element is covered with the first inorganic film. The electrode includes an extending section covering the side surface of the photoelectric conversion element through intermediation of the first inorganic film. That is, the side surface of the photoelectric conversion element is covered with the extending section of the electrode through intermediation of the first inorganic film. Thus, even in a case where the first inorganic film includes a discontinuous part, moisture is less liable to enter the discontinuous part of the first inorganic film, and a leakage current is less liable to flow.

In the first configuration, a second inorganic film covering the extending section may further be included (a second configuration).

According to the second configuration, the extending section is covered with the second inorganic film, and hence an effect of preventing moisture penetration to the discontinuous part of the first inorganic film can be exerted more than the first configuration.

In the second configuration, a third inorganic film covering the second inorganic film may further be included (a third configuration).

According to the third configuration, the second inorganic film is covered with the third inorganic film, and hence an effect of preventing moisture penetration to the discontinuous part of the first inorganic film can be exerted more than the second configuration.

In the first configuration, a first organic film covering the extending section and a second inorganic film covering the first organic film may further be included (a fourth configuration).

According to the fourth configuration, the extending section is covered with the first organic film, and the first organic film is covered with the second inorganic film. Thus, the side surface of the photoelectric conversion element is covered with the first inorganic film, the extending section, the first organic film, and the second inorganic film. Thus, an effect of preventing moisture penetration to the discontinuous part of the first inorganic film can be exerted more than the first configuration.

In the fourth configuration, the second inorganic film may cover a part being the electrode provided on the main surface (a fifth configuration).

According to the fifth configuration, the part being the electrode provided on the main surface of the photoelectric conversion element is covered with the second inorganic film, and hence moisture is less liable to enter the surface of the photoelectric conversion element than the fourth configuration.

In the second configuration, a first organic film may further be included, the first organic film covering the side surface of the photoelectric conversion element through intermediation of the first inorganic film, the extending section may cover a surface of the first organic film, and the second inorganic film may cover an entirety of the electrode including the extending section (a sixth configuration).

According to the sixth configuration, the first inorganic film, the first organic film, and the extending section are layered on the side surface of the photoelectric conversion element, and the entirety of the electrode including the extending section is covered with the second inorganic film. Thus, an effect of preventing moisture penetration to the surface of the photoelectric conversion element and the discontinuous part of the first inorganic film can be exerted more than the second configuration.

In the second configuration, a third inorganic film may further be included, the third inorganic film covering the side surface of the photoelectric conversion element through intermediation of the first inorganic film, the extending section may cover a surface of the third inorganic film, and the second inorganic film may cover an entirety of the electrode including the extending section (a seventh configuration).

According to the seventh configuration, the first inorganic film, the third inorganic film, and the extending section are layered on the side surface of the photoelectric conversion element, and the entirety of the electrode including the extending section is covered with the second inorganic film. Moisture is less liable to penetrate an inorganic film than an organic film. Thus, moisture is less liable to penetrate the discontinuous part of the first inorganic film, and a leakage current is less liable to flow than the fourth configuration.

In any of the first to the seventh configurations, a second organic film covering the second inorganic film may further be included (an eighth configuration).

An X-ray imaging panel includes: the active matrix substrate of any one of the first to eighth configurations; and a scintillator configured to convert an X-ray into scintillation light, the X-ray being emitted (a ninth configuration).

According to the ninth configuration, the discontinuous part of the first inorganic film is covered with the extending section of the electrode through intermediation of the first inorganic film, and hence moisture is less liable to enter the discontinuous part of the first inorganic film. Thus, a leakage current of the photoelectric conversion element is less liable to flow, and detection accuracy of an X-ray can be improved.

A manufacturing method of an active matrix substrate, includes: forming a photoelectric conversion element on a substrate; forming a first inorganic film covering a side surface of the photoelectric conversion element; and forming an electrode on at least one main surface of the photoelectric conversion element, wherein the electrode includes an extending section covering the side surface of the photoelectric conversion element through intermediation of the first inorganic film (a first manufacturing method).

According to the first manufacturing method, even in a case where a discontinuous part is formed in the first inorganic film in the step of forming the first inorganic film covering the side surface of the photoelectric conversion element, the side surface of the photoelectric conversion element is covered with the extending section of the electrode through intermediation of the first inorganic film. Thus, after manufacturing the active matrix substrate, even in a case where moisture enters through a scratch or the like in the active matrix substrate, the moisture is less liable to penetrate the discontinuous part of the first inorganic film, and a leakage current of the photoelectric conversion element is less liable to flow.

A manufacturing method of an active matrix substrate, including: forming a photoelectric conversion element on a substrate; forming a first inorganic film covering a side surface of the photoelectric conversion element; and forming an electrode on at least one main surface of the photoelectric conversion element, and, forming a conductive film, the conductive film being formed of the same material as material of the electrode, being arranged away from the electrode, and covering the side surface of the photoelectric conversion element through intermediation of the first inorganic film (a second manufacturing method).

According to the second manufacturing method, even in a case where a discontinuous part is formed in the first inorganic film in the step of forming the first inorganic film covering the side surface of the photoelectric conversion element, the side surface of the photoelectric conversion element is covered with the conductive film through intermediation of the first inorganic film. Thus, after manufacturing the active matrix substrate, even in a case where moisture enters through a scratch or the like in the active matrix substrate, the moisture is less liable to penetrate the discontinuous part of the first inorganic film, and a leakage current of the photoelectric conversion element is less liable to flow. Further, the conductive film can be formed in the step of forming the electrode, and hence the number of manufacturing processes can be reduced compared to the case where the conductive film is formed by using a material different from that of the electrode.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. An active matrix substrate comprising:
a photoelectric conversion element;
an electrode provided on at least one main surface of the photoelectric conversion element; and
a first inorganic film covering a side surface of the photoelectric conversion element,
wherein the electrode includes an extending section covering the side surface of the photoelectric conversion element through intermediation of the first inorganic film.

2. The active matrix substrate according to claim 1, further comprising:
a second inorganic film covering the extending section.

3. The active matrix substrate according to claim 2, further comprising:
a third inorganic film covering the second inorganic film.

4. The active matrix substrate according to claim 1, further comprising:
a first organic film covering the extending section; and
a second inorganic film covering the first organic film.

5. The active matrix substrate according to claim 4,
wherein the second inorganic film covers a part being the electrode provided on the at least one main surface.

6. The active matrix substrate according to claim 2, further comprising:
a first organic film covering the side surface of the photoelectric conversion element through intermediation of the first inorganic film,
wherein the extending section covers a surface of the first organic film, and
the second inorganic film covers an entirety of the electrode including the extending section.

7. The active matrix substrate according to claim 2, further comprising:
a third inorganic film covering the side surface of the photoelectric conversion element through intermediation of the first inorganic film,
wherein the extending section covers a surface of the third inorganic film, and
the second inorganic film covers an entirety of the electrode including the extending section.

8. The active matrix substrate according to claim 1, further comprising:
a second organic film covering the second inorganic film.

9. An X-ray imaging panel comprising:
the active matrix substrate according to claim 1; and
a scintillator configured to convert an X-ray into scintillation light, the X-ray being emitted.

10. A manufacturing method of an active matrix substrate, the manufacturing method comprising:
forming a photoelectric conversion element on a substrate;
forming a first inorganic film covering a side surface of the photoelectric conversion element; and
forming an electrode on at least one main surface of the photoelectric conversion element,
wherein the electrode includes an extending section covering the side surface of the photoelectric conversion element through intermediation of the first inorganic film.

11. A manufacturing method of an active matrix substrate, the manufacturing method comprising:
forming a photoelectric conversion element on a substrate;
forming a first inorganic film covering a side surface of the photoelectric conversion element; and
forming an electrode on at least one main surface of the photoelectric conversion element, and forming a conductive film, the conductive film being formed of the same material as material of the electrode, being arranged away from the electrode, and covering the side surface of the photoelectric conversion element through intermediation of the first inorganic film.
